(19) United States
(12) Patent Application Publication
(10) Pub. No.: US 2010/0273113 A1
(43) Pub. Date: Oct. 28, 2010

(54) PROCESS FOR PRODUCING PHOTORESIST PATTERN

(75) Inventors: Mitsuhiro HATA, Toyonaka-shi (JP); Akira Kamabuchi, Kobe-shi (JP)

Correspondence Address: BIRCH STEWART KOLASCH & BIRCH, PO BOX 747, FALLS CHURCH, VA, 22040-0747, US

(73) Assignee: Sumitomo Chemical Company, Limited, Tokyo (JP)

(21) Appl. No.: 12/763,675

(22) Filed: Apr. 20, 2010

(30) Foreign Application Priority Data
Apr. 23, 2009 (JP) 2009-104909

(51) Int. Cl. G03F 7/20

(52) U.S. Cl. 430/325

(57) ABSTRACT

The present invention provides a process for producing a photoresist pattern that contains steps (1) to (11)as described in the specification.

This nonprovisional application claims priority under 35 U.S.C. §119(a) on Patent Applications No. 2009-104909 filed in JAPAN on Apr. 23, 2009, the entire contents of which are hereby incorporated by reference.

### FIELD OF THE INVENTION

The present invention relates to a process for producing a photoresist pattern.

### BACKGROUND OF THE INVENTION

In recent years, a more miniaturized photoresist pattern has been demanded to produce in a process of production of a semiconductor using a lithography technology. As a process realizing to form a photoresist pattern having a line width of 32 nm or less, a double-patterning method has been proposed (e.g. Japanese Patent Laid-Open No. 2007-311508). The double-patterning method is a method in which a target photoresist pattern is formed by performing twice a pattern transfer step. According to the double-patterning method, a first photoresist pattern is formed at a pitch twice a target pitch via ordinary exposure and development, and thereafter, in a space between lines of the first photoresist pattern, a second photoresist pattern having the same pitch is formed by performing exposure and development again, and a target fine photoresist pattern is thereby formed.

### SUMMARY OF THE INVENTION

An object of the present invention is to provide a process for producing a photoresist pattern.

The present invention relates to the followings:

<1> A process for producing a photoresist pattern comprising the following steps (1) to (11):

(1) a step of applying the first photoresist composition comprising:
(a) a resin comprising a structural unit having an acid-labile group in its side chain and being itself insoluble or poorly soluble in an alkali aqueous solution but becoming soluble in an alkali aqueous solution by the action of an acid,
(b) an acid generator, and
(c) a cross-linking agent represented by the formula (X):

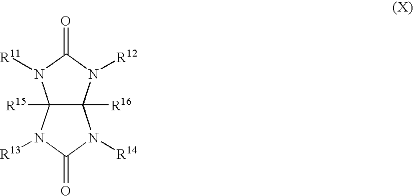

wherein R¹¹, R¹², R¹³ and R¹⁴ each independently represent a C1-C6 alkyl group substituted with a C1-C6 alkoxy group, and R¹⁵ and R¹⁶ each independently represent a C1-C6 alkyl group or a C6-C10 aromatic hydrocarbon group which may have one or more substituents, on a substrate followed by conducting drying, thereby forming the first photoresist film,

(2) a step of prebaking the first photoresist film,

(3) a step of exposing the prebaked first photoresist film to radiation,

(4) a step of baking the exposed first photoresist film,

(5) a step of developing the baked first photoresist film with the first alkaline developer, thereby forming the first photoresist pattern,

(6) a step of making the formed first photoresist pattern inactive to radiation in the following step (9), making the formed first photoresist pattern insoluble in an alkaline developer or making the formed first photoresist pattern insoluble in the second photoresist composition used in the following step (7),

(7) a step of applying the second photoresist composition on the substrate on which the first photoresist pattern has been formed, followed by conducting drying, thereby forming the second photoresist film,

(8) a step of prebaking the second photoresist film,

(9) a step of exposing the prebaked second photoresist film to radiation,

(10) a step of baking the exposed second photoresist film, and

(11) a step of developing the baked second photoresist film with the second alkaline developer, thereby forming the second photoresist pattern;

<2> The process according to <1>, wherein the step (6) is a step of baking the formed first photoresist pattern;
<3> The process according to <1> or <2>, wherein R¹¹, R¹², R¹³ and R¹⁴ each independently represent a methoxymethyl group or an isopropoxymethyl group in the formula (X);
<4> The process according to <1>, <2> or <3>, wherein R¹⁵ and R¹⁶ each independently represent a methyl group, a propyl group or a phenyl group in the formula (X);
<5> The process according to any one of <1> to <4>, wherein the amount of the cross-linking agent represented by the formula (X) is 0.5 to 30 parts by weight per 100 parts by weight of the resin in the first photoresist composition;
<6> The process according to any one of <1> to <5>, wherein the resin further comprises a structural unit derived from a hydroxyl-containing adamantyl acrylate or a hydroxyl-containing adamantyl methacrylate;
<7> The process according to <6>, wherein the content of the structural unit derived from a hydroxyl-containing adamantyl acrylate or a hydroxyl-containing adamantyl methacrylate is 5 to 50% by mole based on 100% by mole of all of the structural units of the resin;
<8> The process according to any one of <1> to <7>, wherein the structural unit having an acid-labile group in its side chain is derived from an acrylic acid ester or a methacrylic acid ester wherein a carbon atom adjacent to the oxygen atom in the ester part is a quaternary carbon atom and the acrylic acid ester and the methacrylic acid ester have 5 to 30 carbon atoms;
<9> The process according to any one of <1> to <8>, wherein the content of the resin is 70 to 99.9% by weight based on the amount of solid components in the first photoresist composition;
<10> The process according to any one of <1> to <9>, wherein the acid generator is a salt represented by the formula (I):

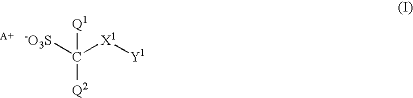

wherein Q¹ and Q² each independently represent a fluorine atom or a C1-C6 perfluoroalkyl group, X¹ represents a single bond or —(CH₂)ₖ—in which one or more methylene groups may be replaced by —O— or —CO—, and one or more hydrogen atoms may be replaced by a linear or branched chain C1-C4 aliphatic hydrocarbon group, and k represents an integer of 1 to 17, Y¹ represents a C3-C36 cyclic hydrocarbon group which may have one or more substituents, and one or more methylene groups in the cyclic hydrocarbon group may be replaced by —O— or —CO—, and A⁺ represents an organic counter ion;
<11> The process according to any one of <1> to <10>, wherein the content of the acid generator is 0.1 to 30% by weight based on the amount of solid components in the first photoresist composition.

### DESCRIPTION OF PREFERRED EMBODIMENTS

The first photoresist composition using in the present invention comprises the following three components;

Component (a): a resin comprising a structural unit having an acid-labile group in its side chain and being itself insoluble or poorly soluble in an alkali aqueous solution but becoming soluble in an alkali aqueous solution by the action of an acid,

Component (b): an acid generator, and

Component (c): a cross-linking agent represented by the formula (X):

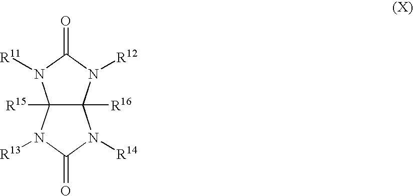

wherein R¹¹, R¹², R¹³ and R¹⁴ each independently represent a C1-C6 alkyl group substituted with a C1-C6 alkoxy group, and R¹⁵ and R¹⁶ each independently represent a C1-C6 alkyl group or a C6-C10 aromatic hydrocarbon group which may have one or more substituents (hereinafter, simply referred to as the cross-linking agent (X)).

“C1-C6 alkyl group” means an alkyl group having one to six carbon atoms.

First, Component (a) will be illustrated.

In this specification, “the resin is itself insoluble or poorly soluble in an alkali aqueous solution” means 100 mL or more of an alkali aqueous solution is needed to dissolve 1 g or 1 mL of the first photoresist composition containing the resin, and “the resin is soluble in an alkali aqueous solution” means less than 100 mL of an alkali aqueous solution is needed to dissolve 1 g or 1 mL of the first photoresist composition containing the resin.

In this specification, “an acid-labile group” means a group capable of being eliminated by the action of an acid.

In this specification, “—COOR” may be described as “a structure having ester of carboxylic acid”, and may also be abbreviated as “ester group”. Specifically, “—COOC(CH₃)₃” may be described as “a structure having tert-butyl ester of carboxylic acid”, or be abbreviated as “tert-butyl ester group”.

Examples of the acid-labile group include a structure having ester of carboxylic acid such as alkyl ester group in which a carbon atom adjacent to the oxygen atom is quaternary carbon atom, alicyclic ester group in which a carbon atom adjacent to the oxygen atom is quaternary carbon atom, and a lactone ester group in which a carbon atom adjacent to the oxygen atom is quaternary carbon atom. The “quaternary carbon atom” means a “carbon atom joined to four substituents other than hydrogen atom”. Other examples of the acid-labile group include a group having a quaternary carbon atom joined to three carbon atoms and an —OR', wherein R′ represents an alkyl group.

Examples of the acid-labile group include an alkyl ester group in which a carbon atom adjacent to the oxygen atom is quaternary carbon atom such as a tert-butyl ester group; an acetal type ester group such as a methoxymethyl ester, ethoxymethyl ester, 1-ethoxyethyl ester, 1-isobutoxyethyl ester, 1-isopropoxyethyl ester, 1-ethoxypropoxy ester, 1-(2-methoxyethoxy)ethyl ester, 1-(2-acetoxyethoxy)ethyl ester, 1-[2-(1-adamantyloxy)ethoxy]ethyl ester, 1-[2-(1-adamantanecarbonyloxy)ethoxy]ethyl ester, tetrahydro-2-furyl ester and tetrahydro-2-pyranyl ester group; an alicyclic ester group in which a carbon atom adjacent to the oxygen atom is quaternary carbon atom, such as an isobornyl ester, 1-alkylcycloalkyl ester, 2-alkyl-2-adamantyl ester and 1-(1-adamantyl)-1-alkylalkyl ester group. The above-mentioned adamantyl group may have one or more hydroxyl groups.

As the acid-labile group, a group represented by the formula (1a):

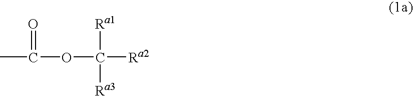

wherein R^{a1}, R^{a2} and R^{a3} independently each represent a C1-C8 aliphatic hydrocarbon group or a C3-C20 saturated cyclic hydrocarbon group, or R^{a1} and R^{a2} are bonded each other to form a C3-C20 ring, is preferable.

Examples of the C1-C8 aliphatic hydrocarbon group include a C1-C8 alkyl group such as a methyl group, an ethyl group, a propyl group, an isopropyl group, a butyl group, a pentyl group, a hexyl group, a heptyl group and an octyl group. The C3-C20 saturated cyclic hydrocarbon group may be monocyclic or polycyclic, and examples thereof include a monocyclic saturated cyclic hydrocarbon group such as a C3-C20 cycloalkyl group (e.g. a cyclopentyl group, a cyclohexyl group, a methylcyclohexyl group, a dimethylcyclohexyl group, a cycloheptyl group and a cyclooctyl group), a group wherein a C10-C20 condensed aromatic hydrocarbon group is hydrogenated such as a hydronaphthyl group), a C7-C20 bridged cyclic hydrocarbon group such as an adamantly group, a norbornyl group and a methylnorbornyl group, and the followings:

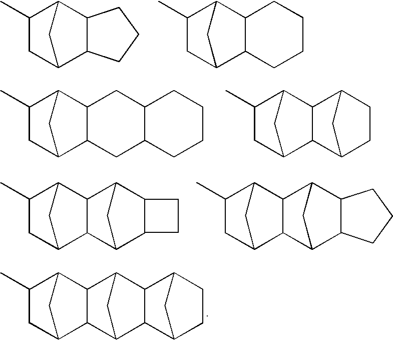

The saturated cyclic hydrocarbon group preferably has 3 to 12 carbon atoms.

Examples of the ring formed by bonding R^{a1} and R^{a2} each other include a saturated hydrocarbon ring and aromatic ring, and these rings preferably have 3 to 12 carbon atoms.

The group represented by the formula (1a) wherein R^{a1}, R^{a2} and R^{a3} independently each represent a C1-C8 alkyl group such as a tert-butyl group, the group represented by the formula (1a) wherein R^{a1} and R^{a2} are bonded each other to form an adamantyl ring and R^{a3} is a C1-C8 alkyl group such as a 2-alkyl-2-adamantyl group, and the group represented by the formula (1a) wherein R^{a1} and R^{a2} are C1-C8 alkyl groups and R^{a3} is an adamantyl group such as a 1-(1-adamantyl)-1-alkylalkoxycarbonyl group are more preferable.

Examples of the structural unit having an acid-labile group in its side chain include a structure unit derived from an ester of acrylic acid, a structural unit derived from an ester of methacrylic acid, a structural unit derived from an ester of norbornenecarboxylic acid, a structural unit derived from an ester of tricyclodecenecarboxylic acid and a structural unit derived from an ester of tetracyclodecenecarboxylic acid. The structure units derived from the ester of acrylic acid and from the ester of methacrylic acid are preferable, and the structural unit derived from an acrylic acid ester or a methacrylic acid ester wherein a carbon atom adjacent to the oxygen atom in the ester part is a quaternary carbon atom and the acrylic acid ester and the methacrylic acid ester have 5 to 30 carbon atoms is more preferable.

The resin can be obtained by conducting polymerization reaction of a monomer or monomers having the acid-labile group and an olefinic double bond. The polymerization reaction is usually carried out in the presence of a radical initiator.

Among the monomers, those having a bulky and acid-labile group such as a saturated cyclic hydrocarbon ester group (e.g. a 1-alkyl-1-cyclohexyl ester group, a 2-alkyl-2-adamantyl ester group and 1-(1-adamantyl)-1-alkylalkyl ester group) are preferable, since excellent resolution is obtained when the resin obtained is used in the photoresist composition. Especially, monomers having a saturated cyclic hydrocarbon ester group containing a bridged structure such as a 2-alkyl-2-adamantyl ester group and 1-(1-adamantyl)-1-alkylalkyl ester group are more preferable.

Examples of such monomer containing the bulky and acid-labile group include a 1-alkyl-1-cyclohexyl acrylate, a 1-alkyl-1-cyclohexyl methacrylate, a 2-alkyl-2-adamantyl acrylate, a 2-alkyl-2-adamantyl methacrylate, 1-(1-adamantyl)-1-alkylalkyl acrylate, a 1-(1-adamantyl)-1-alkylalkyl methacrylate, a 2-alkyl-2-adamantyl 5-norbornene-2-carboxylate, a 1-(1-adamantyl)-1-alkylalkyl 5-norbornene-2-carboxylate, a 2-alkyl-2-adamantyl α-chloroacrylate and a 1-(1-adamantyl)-1-alkylalkyl α-chloroacrylate.

Particularly when the 2-alkyl-2-adamantyl acrylate, the 2-alkyl-2-adamantyl methacrylate or the 2-alkyl-2-adamantyl α-chloroacrylate is used as the monomer for the resin component in the photoresist composition, a photoresist composition having excellent resolution tend to be obtained. Typical examples thereof include 2-methyl-2-adamantyl acrylate, 2-methyl-2-adamantyl methacrylate, 2-ethyl-2-adamantyl acrylate, 2-ethyl-2-adamantyl methacrylate, 2-isopropyl-2-adamantyl acrylate, 2-isopropyl-2-adamantyl methacrylate, 2-n-butyl-2-adamantyl acrylate, 2-methyl-2-adamantyl α-chloroacrylate and 2-ethyl-2-adamantyl α-chloroacrylate.

When particularly 2-ethyl-2-adamantyl acrylate, 2-ethyl-2-adamantyl methacrylate, 2-isopropyl-2-adamantyl acrylate or 2-isopropyl-2-adamantyl methacrylate is used for the photoresist composition, a photoresist composition having excellent sensitivity and heat resistance tends to be obtained. Two or more kinds of monomers having a group or groups dissociated by the action of the acid may be used together, if necessary.

The 2-alkyl-2-adamantyl acrylate can be usually produced by reacting a 2-alkyl-2-adamantanol or a metal salt thereof with an acrylic halide, and the 2-alkyl-2-adamantyl methacrylate can be usually produced by reacting a 2-alkyl-2-adamantanol or a metal salt thereof with a methacrylic halide.

Examples of the 1-alkyl-1-cyclohexyl acrylate include 1-ethyl-1-cyclohexyl acrylate, and examples of the 1-alkyl-1-cyclohexyl methacrylate include 1-ethyl-1-cyclohexyl methacrylate.

The resin can also contain one or more structural units having one or more highly polar substituents. Examples of the structural unit having one or more highly polar substituents include a structural unit having a hydrocarbon group having at least one selected from the group consisting of a hydroxyl group, a cyano group, a nitro group and an amino group and a structural unit having a hydrocarbon group having one or more —CO—O—, —CO—, —O—, —SO₂— or —S—. A structural unit having a saturated cyclic hydrocarbon group having a cyano group or a hydroxyl group, a structural unit having a saturated cyclic hydrocarbon group in which one or more —CH₂— replaced by —O— or —CO—, and a structural unit having a lactone structure in its side chain are preferable, and a structural unit having a bridged hydrocarbon group having one or more hydroxyl groups, and a structural unit having a bridged hydrocarbon group having —CO—O— or —CO— are more preferable. Examples thereof include a structural unit derived from 2-norbornene having one or more hydroxyl groups, a structural unit derived from acrylonitrile or methacrylonitrile, a structural unit derived from an alkyl acrylate or an alkyl methacrylate in which a carbon atom adjacent to oxygen atom is secondary or tertiary carbon atom, a structural unit derived from hydroxyl-containing adamantyl acrylate or hydroxyl-containing adamantyl methacrylate, a structural unit derived from styrene monomer such as p-hydroxystyrene and m-hydroxystyrene, a structural unit derived from a structural unit derived from 1-adamantyl acrylate or 1-adamantyl methacrylate, and a structural unit derived from acryloyloxy-γ-butyrolactone or methacryloyloxy-γ-butyrolactone having a lactone ring which may have an alkyl group. Among them, a structural unit derived from hydroxyl-containing adamantyl acrylate or hydroxyl-containing adamantyl methacrylate, and a structural unit derived from carbonyl-containing adamantyl acrylate or carbonyl-containing adamantyl methacrylate are preferable. Herein, the 1-adamantyloxycarbonyl group is the acid-stable group though the carbon atom adjacent to oxygen atom is the quaternary carbon atom.

When the resin has a structural unit derived from hydroxyl-containing adamantyl acrylate or hydroxyl-containing adamantyl methacrylate, the content thereof is preferably 5 to 50% by mole based on 100% by mole of all the structural units of the resin.

Examples of the monomer giving the structural unit derived from carbonyl-containing adamantyl acrylate or carbonyl-containing adamantyl methacrylate include monomers represented by the formulae (a1) and (a2):

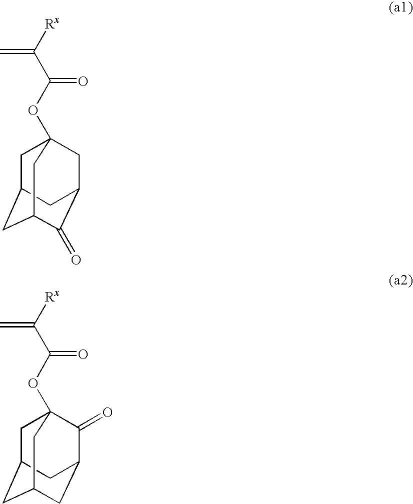

wherein R^{x} represents a hydrogen atom or a methyl group, and the monomer represented by the formula (a2) is preferable.

When the resin has a structural unit derived from the monomer represented by the formula (a1), the content thereof is preferably 2 to 20% by mole based on 100% by mole of all the structural units of the resin.

Specific examples of the structural unit having one or more highly polar substituents include a structural unit derived from
3-hydroxy-1-adamantyl acrylate;
a structural unit derived from 3-hydroxy-1-adamantyl methacrylate;
a structural unit derived from 3,5-dihydroxy-1-adamantyl acrylate;
a structural unit derived from 3,5-dihydroxy-1-adamantyl methacrylate;
a structural unit derived from α-acryloyloxy-γ-butyrolactone;
a structural unit derived from α-methacryloyloxy-γ-butyrolactone;
a structural unit derived from β-acryloyloxy-γ-butyrolactone;
a structural unit derived from β-methacryloyloxy-γ-butyrolactone;
a structural unit represented by the formula (a):

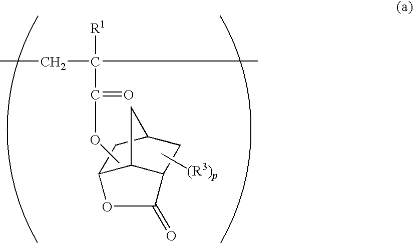

wherein R¹ represents a hydrogen atom or a methyl group, R³ is independently in each occurrence a methyl group, a trifluoromethyl group or a halogen atom, and p represents an integer of 0 to 3; and a structural unit represented by the formula (b):

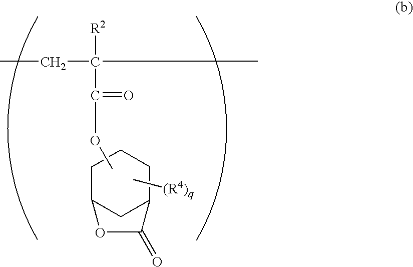

wherein R² represents a hydrogen atom or a methyl group, R⁴ is independently in each occurrence a methyl group, a trifluoromethyl group or a halogen atom, and q represents an integer of 0 to 3.

Among them, the resin having at least one structural unit selected from the group consisting of the structural unit derived from 3-hydroxy-1-adamantyl acrylate, the structural unit derived from 3-hydroxy-1-adamantyl methacrylate, the structural unit derived from 3,5-dihydroxy-1-adamantyl acrylate, the structural unit derived from 3,5-dihydroxy-1-adamantyl methacrylate, the structural unit derived from α-acryloyloxy-γ-butyrolactone; the structural unit derived from α-methacryloyloxy-γ-butyrolactone; the structural unit derived from β-acryloyloxy-γ-butyrolactone and the structural unit derived from β-methacrYloyloxy-γ-butyrolactone is preferable from the standpoint of the adhesiveness of photoresist to a substrate and resolution of photoresist.

3-Hydroxy-1-adamantyl acrylate, 3-hydroxy-1-adamantyl methacrylate, 3,5-dihydroxy-1-adamantyl acrylate and 3,5-dihydroxy-1-adamantyl methacrylate can be produced, for example, by reacting corresponding hydroxyadamantane with acrylic acid, methacrylic acid or its acid halide, and they are also commercially available.

Further, the acryloyloxy-γ-butyrolactone and the methacryloyloxy-γ-butyrolactone can be produced by reacting corresponding α- or β-bromo-γ-butyrolactone with acrylic acid or methacrylic acid, or reacting corresponding α- or β-hydroxy-γ-butyrolactone with the acrylic halide or the methacrylic halide.

Examples of the monomers giving structural units represented by the formulae (a) and (b) include an acrylate of alicyclic lactones and a methacrylate of alicyclic lactones having the hydroxyl group described below, and mixtures thereof. These esters can be produced, for example, by reacting the corresponding alicyclic lactone having the hydroxyl group with acrylic acid or methacrylic acid, and the production method thereof is described in, for example, JP 2000-26446 A.

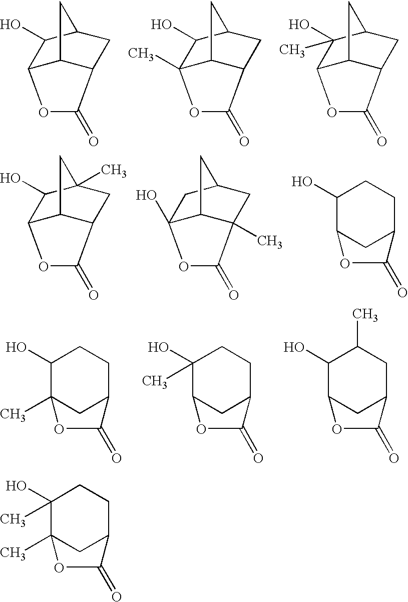

Examples of the acryloyloxy-γ-butyrolactone and the methacryloyloxy-γ-butyrolactone in which lactone ring may be substituted with the alkyl group include
α-acryloyloxy-γ-butyrolactone, α-methacryloyloxy-γ-butyrolactone,
α-acryloyloxy-ββ-dimethyl-γ-butyrolactone,
α-methacryloyloxy-ββ-dimethyl-γ-butyrolactone,
α-acryloyloxy-α-methyl-γ-butyrolactone,
α-methacryloyloxy-α-methyl-γ-butyrolactone,
β-acryloyloxy-γ-butyrolactone, β-methacryloyloxy-γ-butyrolactone and β-methacryloyloxy-α-methyl-γ-butyrolactone.

When the exposing is conducted using KrF excimer laser, the resin preferably has a structural unit derived from a styrene monomer such as p-hydroxystyrene and m-hydroxystyrene.

The resin can contain a structural unit derived from acrylic acid or methacrylic acid, a structural unit derived from an alicyclic compound having an olefinic double bond such as a structural unit represented by the formula (c):

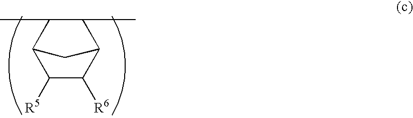

wherein R⁵ and R⁶ each independently represents a hydrogen atom, a C1-C3 alkyl group, a carboxyl group, a cyano group or a —COOU group in which U represents an alcohol residue, or R⁵ and R⁶ can be bonded together to form a carboxylic anhydride residue represented by —C(═O)OC(═O)—,
a structural unit derived from an aliphatic unsaturated dicarboxylic anhydride such as a structural unit represented by the formula (d):

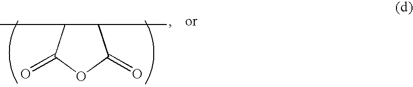

or a structural unit represented by the formula (e):

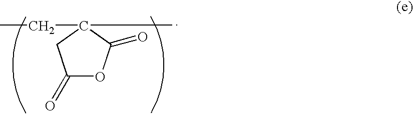

In R⁵ and R⁶, examples of the C1-C3 alkyl group include a methyl group, an ethyl group, a propyl group and an isopropyl group. The —COOU group is an ester formed from the carboxyl group, and examples of the alcohol residue corresponding to U include an optionally substituted C1-C8 alkyl group, 2-oxooxolan-3-yl group and 2-oxooxolan-4-yl group, and examples of the substituent on the C1-C8 alkyl group include a hydroxyl group and an alicyclic hydrocarbon group.

Specific examples of the monomer giving the structural unit represented by the above-mentioned formula (c) may include 2-norbornene, 2-hydroxy-5-norbornene, 5-norbornene-2-carboxylic acid, methyl 5-norbornene-2-carboxylate, 2-hydroxyethyl 5-norbornene-2-carboxylate, 5-norbornene-2-methanol and 5-norbornene-2,3-dicarboxylic anhydride.

When U in the —COOU group is the acid-labile group, the structural unit represented by the formula (c) is a structural unit having the acid-labile group even if it has the norbornane structure. Examples of monomers giving a structural unit having the acid-labile group include tert-butyl 5-norbornene-2-carboxylate, 1-cyclohexyl-1-methylethyl 5-norbornene-2-carboxylate, 1-methylcyclohexyl 5-norbornene-2-carboxylate, 2-methyl-2-adamantyl 5-norbornene-2-carboxylate, 2-ethyl-2-adamantyl 5-norbornene-2-carboxylate, 1-(4-methylcyclohexyl)-1-methylethyl 5-norbornene-2-carboxylate, 1-(4-hydroxycyclohexyl)-1-methylethyl 5-norbornene-2-carboxylate, 1-methyl-1-(4-oxocyclohexyl)ethyl 5-norbornene-2-carboxylate and 1-(1-adamantyl)-1-methylethyl 5-norbornene-2-carboxylate.

The content of the structural unit having an acid-labile group in the resin is usually 10 to 80% by mole based on total molar of all the structural units of the resin.

When the resin has the structural unit derived from 2-alkyl-2-adamantyl acrylate, 2-alkyl-2-adamantyl methacrylate, 1-(1-adamantyl)-1-alkylalkyl acrylate or 1-(1-adamantyl)-1-alkylalkyl methacrylate, the content thereof is preferably 15% by mole or more based on total molar of all the structural units of the resin.

The resin usually has 10,000 or more of the weight-average molecular weight, preferably 10,500 or more of the weight-average molecular weight, more preferably 11,000 or more of the weight-average molecular weight, much more preferably 11,500 or more of the weight-average molecular weight, and especially preferably 12,000 or more of the weight-average molecular weight. When the weight-average molecular weight of the resin is too large, defect of the photoresist film tends to generate, and therefore, the resin preferably has 40,000 or less of the weight-average molecular weight, more preferably 39,000 or less of the weight-average molecular weight, much more preferably 38,000 or less of the weight-average molecular weight, and especially preferably 37,000 or less of the weight-average molecular weight. The weight-average molecular weight can be measured with gel permeation chromatography.

Component (a) contains one or more resins.

In the first photoresist composition, the content of Component (a) is usually 70 to 99.9% by weight based on the amount of solid components. In this specification, “solid components” means sum of components other than a solvent (s) in the photoresist composition.

Next, Component (b) will be illustrated.

The acid generator is a substance which is decomposed to generate an acid by applying a radiation such as a light, an electron beam or the like on the substance itself or on a photoresist composition containing the substance. The acid generated from the acid generator acts on the resin resulting in cleavage of the acid-labile group existing in the resin, and the resin becomes soluble in an aqueous alkali solution.

The acid generator may be nonionic or ionic. Examples of the nonionic acid generator include organic halides, sulfonate esters such as 2-nitrobenzyl ester, aromatic sulfonate, oxime sulfonate, N-sulfonyloxyimide, sulfonyloxyketone and DNQ 4-sulfonate, and sulfones such as disulfone, ketosulfone and sulfonyldiazomethane. Examples of the ionic acid generator include onium salts such as a diazonium salt, a phosphonium salt, a sulfonium salt and an iodonium salt, and examples of the anion of the onium salt include sulfonic acid anion, sulfonylimide anion and sulfonylmethide anion.

A fluorine-containing acid generator is preferable, and a salt represented by the formula (I):

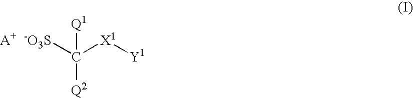

wherein Q¹ and Q² each independently represent a fluorine atom or a C1-C6 perfluoroalkyl group, X¹ represents a single bond or —(CH₂)ₖ—in which one or more methylene groups may be replaced by —O— or —CO—, and one or more hydrogen atoms may be replaced by a linear or branched chain C1-C4 aliphatic hydrocarbon group, and k represents an integer of 1 to 17, Y¹ represents a C3-C36 cyclic hydrocarbon group which may have one or more substituents, and one or more methylene groups in the cyclic hydrocarbon group may be replaced by —O— or —CO—, and A⁺ represents an organic counter ion, is more preferable.

Examples of the C1-C6 perfluoroalkyl group include a trifluoromethyl group, a pentafluoroethyl group, a heptafluoropropyl group, a nonafluorobutyl group, an undecafluoropentyl group and a tridecafluorohexyl group, and a trifluoromethyl group is preferable. It is preferred that Q¹ and Q² each independently represent a fluorine atom or a trifluoromethyl group, and it is more preferred that Q¹ and Q² represent fluorine atoms.

Examples of the linear or branched chain C1-C4 aliphatic hydrocarbon group include a linear or branched chain C1-C4 alkyl group such as a methyl group, an ethyl group, a propyl group, an isopropyl group, a butyl group, a sec-butyl group and a tert-butyl group.

Examples of —(CH₂)ₖ— in which one or more hydrogen atoms may be replaced by a linear or branched chain C1-C4 aliphatic hydrocarbon group include a methylene group, a dimethylene group, a trimethylene group, a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, a tetradecamethylene group, a pentadecamethylene group, a hexadecamethylene group, a heptadecamethylene group, a propane-1,2-diyl group, a 2-methylpropane-1,3-diyl group, a butane-1,3-diyl group. Examples of —(CH₂)ₖ— in which one or more methylene groups may be replaced by —O— or —CO— include —CO—O—X¹¹—*, —O—CO—X¹¹—*, —X¹¹—CO—O—*, —X¹¹—O—CO—*, —O—X¹²—*, —X¹²—O—*, —X¹³—O—X¹⁴—*, —CO—O—X¹⁵—CO—O—* and —CO—O—X¹⁶—O—* wherein * is a bonding site for Y¹, X¹¹ is a C1-C15 linear or branched alkylene group, X¹² is a C1-C16 linear or branched alkylene group, X¹³ is a C1-C15 linear or branched alkylene group, X¹⁴ is a C1-C15 linear or branched alkylene group, the total of carbon numbers of X¹³ and X¹⁴ is 16 or less, X¹⁵ is a C1-C13 linear or branched alkylene group, and X¹⁶ is a C1-C14 linear or branched alkylene group, and —CO—O—X¹¹—*, —X¹²—O—*, and —X¹¹—CO—O—* are preferable and —CO—O—X¹¹—* and —X¹¹—CO—O—* are preferable and —CO—O—X¹¹—* and —X¹¹—CO—O—* are more preferable, and —CO—O—X¹¹—* is especially preferable.

X¹ is preferably —CO—O— or —CO—O—X¹⁷ wherein X¹⁷ is a C1-C4 linear or branched alkylene group.

Examples of the C3-C36 cyclic hydrocarbon group include a saturated cyclic hydrocarbon group such as a cyclopropyl group, a cyclobutyl group, a cyclopentyl group, a cyclohexyl group, a cycloheptyl group, a cyclooctyl group, a cyclononyl group, a cyclodecyl group, a norbornyl group, a 1-adamantyl group, a 2-adamantyl group, an isobornyl group, and the followings,

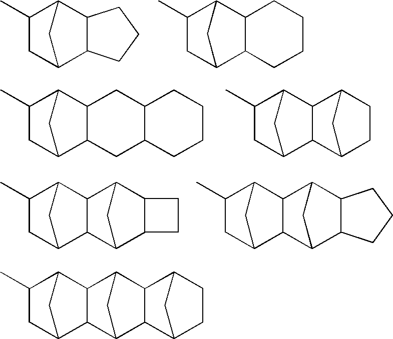

and an aromatic hydrocarbon group such as the followings.

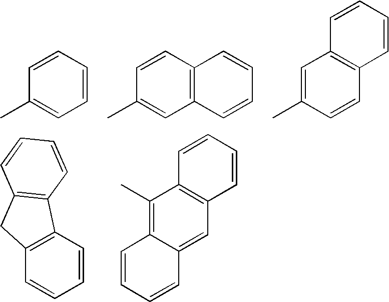

The C3-C36 cyclic hydrocarbon group may have one or more substituents, and one or more methylene groups therein may be replaced by —O— or —CO—. Examples of the substituent include a halogen atom, a hydroxyl group, a linear or branched chain C1-C12 hydrocarbon group, a C1-C6 hydroxyalkyl group, a C6-C20 aromatic hydrocarbon group, a C7-C21 aralkyl group, a glycidyloxy group and a C2-C4 acyl group. Examples of the halogen atom include a fluorine atom, a chlorine atom, a bromine atom and an iodine atom. Examples of the linear or branched chain C1-C12 hydrocarbon group include the above-mentioned aliphatic hydrocarbon group. Examples of the C1-C6 hydroxyalkyl group include a hydroxymethyl group, a 2-hydroxyethyl group, a 3-hydroxypropyl group, a 4-hydroxybutyl group, a 5-hydroxypentyl group and a 6-hydroxyhexyl group. Examples of the C6-C20 aromatic hydrocarbon group include a phenyl group, a naphthyl group, an anthryl group, a p-methylphenyl group, a p-tert-butylphenyl group and a p-adamantylphenyl group. Examples of the C7-C21 aralkyl group include a benzyl group, a phenethyl group, a phenylpropyl group, a trityl group, a naphthylmethyl group and a naphthylethyl group. Examples of the C2-C4 acyl group include an acetyl group, a propionyl group and a butyryl group.

As the acid generator, a salt represented by the formula (B):

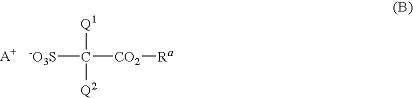

wherein Q¹, Q² and A⁺ are the same meanings as defined above, and Ra represents a linear or branched chain C1-C6 aliphatic hydrocarbon group, or a C3-C30 saturated cyclic hydrocarbon group which can have one or more substituents selected from the group consisting of a C1-C6 alkoxy group, a C1-C4 perfluoroalkyl group, a hydroxyl group and a cyano group.

As the acid generator, a salt represented by the formula (V) or (VI):

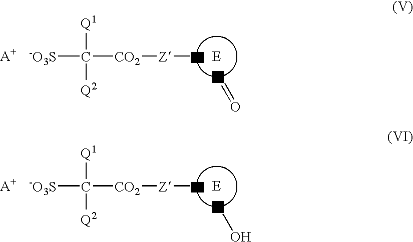

wherein ring E represents a C3-C30 cyclic hydrocarbon group which can have a C1-C6 alkyl group, a C1-C6 alkoxy group, a C1-C4 perfluoroalkyl group, a C1-C6 hydroxyalkyl group, a hydroxyl group or a cyano group, Z′ represents a single bond or a C1-C4 alkylene group, and Q¹, Q² and A⁺ are the same meanings as defined above.

Examples of the C1-C4 alkylene group include a methylene group, a dimethylene group, a trimethylene group and a tetramethylene group, and a methylene group and a dimethylene group are preferable.

As the acid generator, a salt represented by the formula (III):

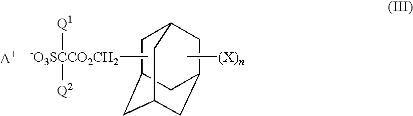

wherein Q¹, Q² and A⁺ are the same meanings as defined above, and X independently each represents a hydroxyl group or a C1-C6 hydroxyalkylene group, and n represents an integer of 0 to 9, is more preferable, and the salt represented by the formula (III) wherein n is 1 or 2 is especially preferable.

Examples of the anions of the salts represented by the formulae (III), (V) and (VI) include the followings.

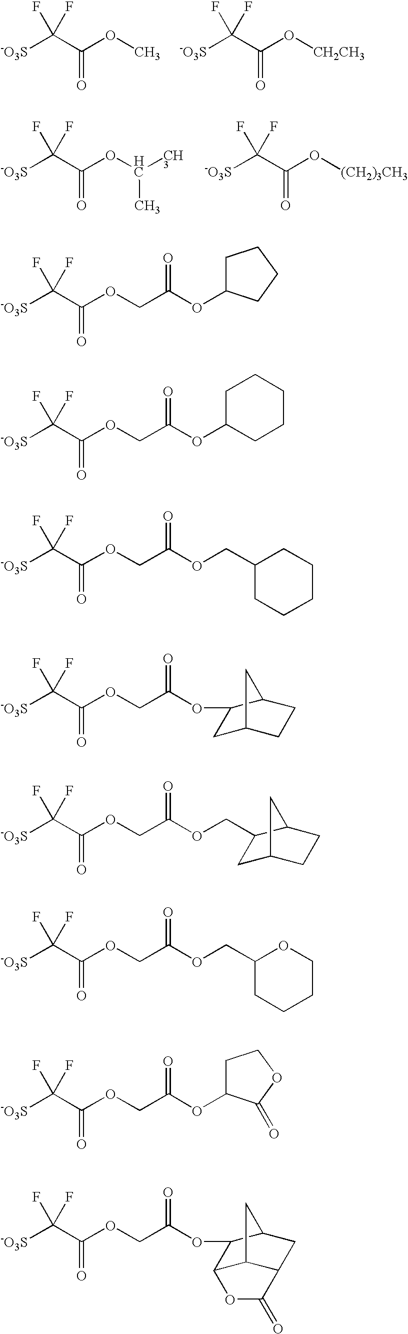

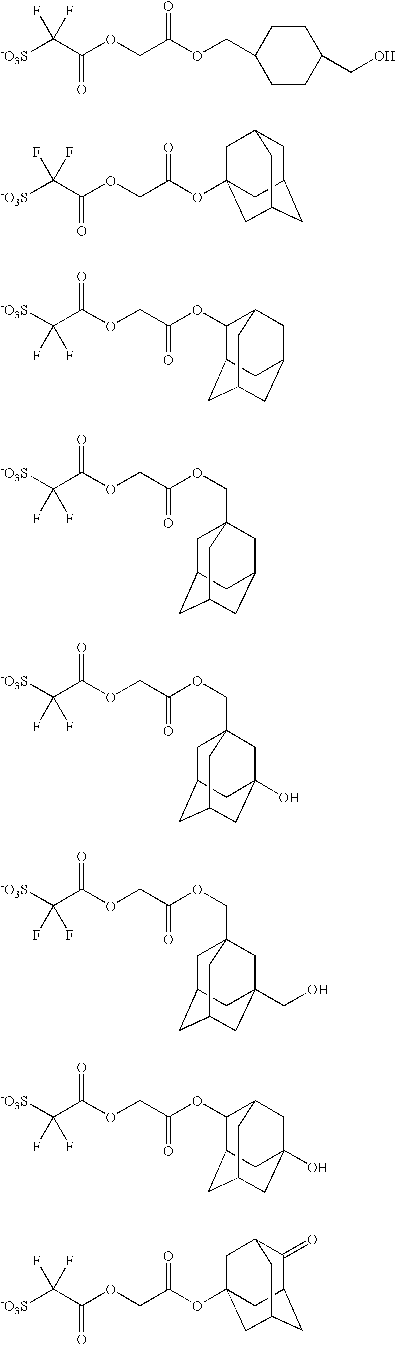

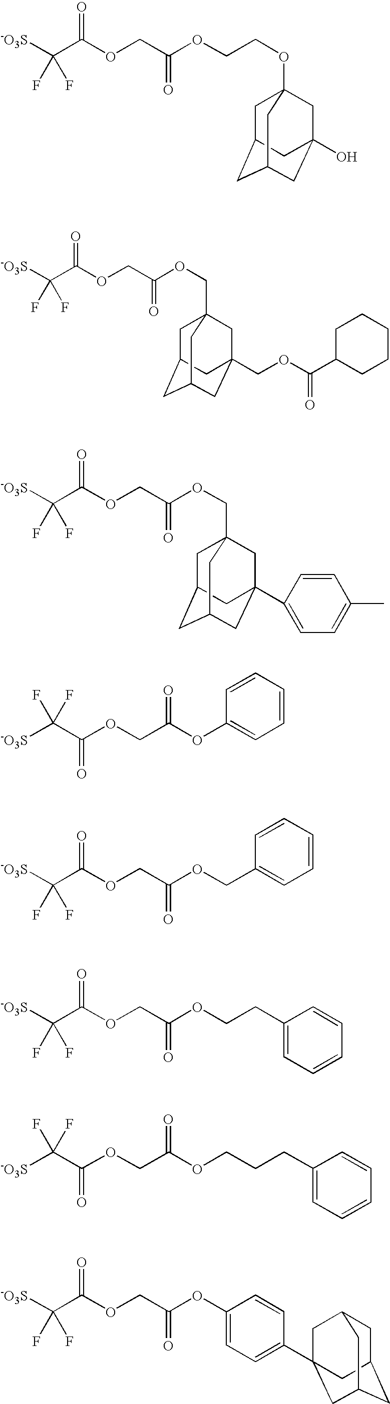

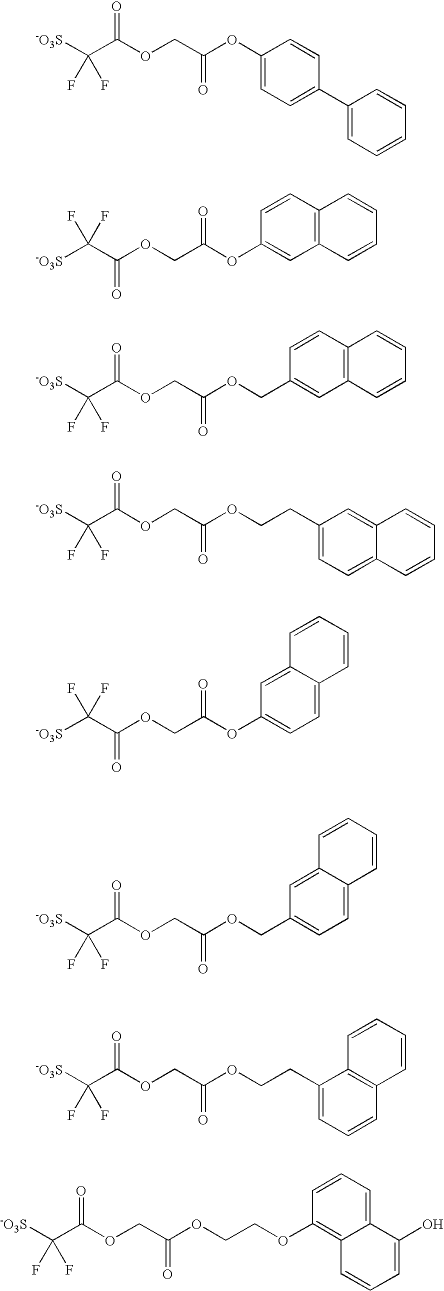

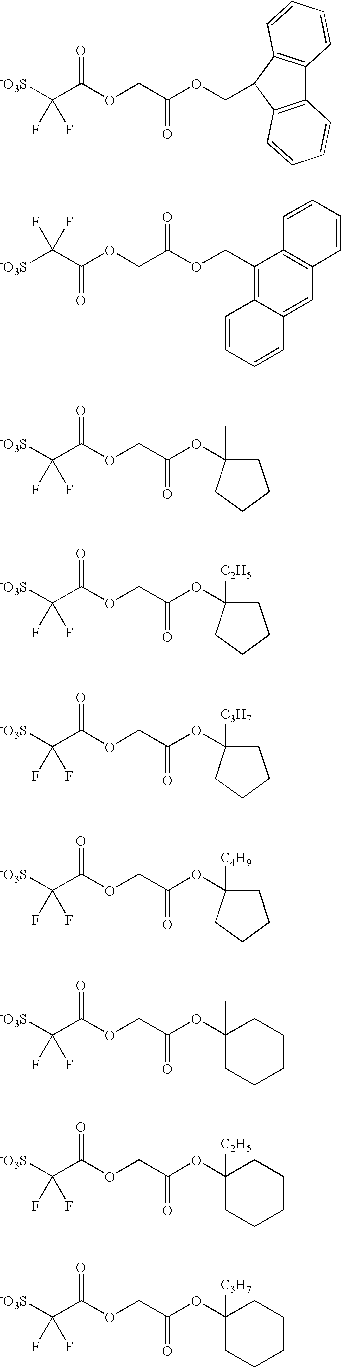

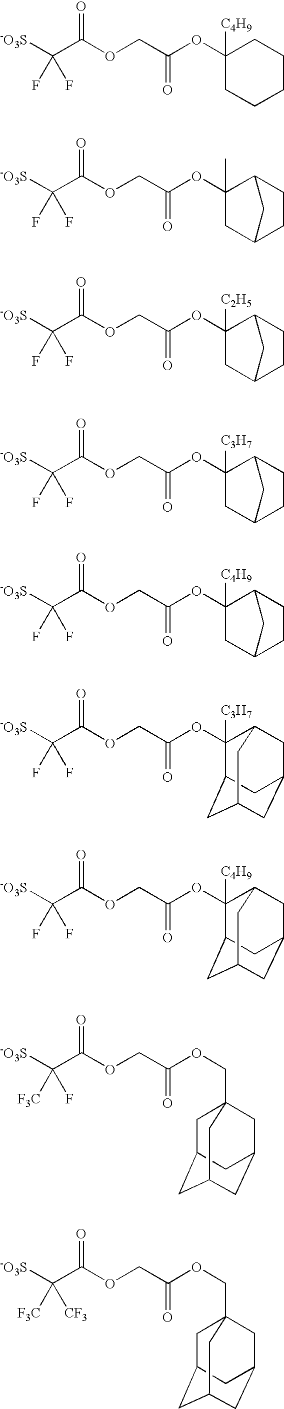

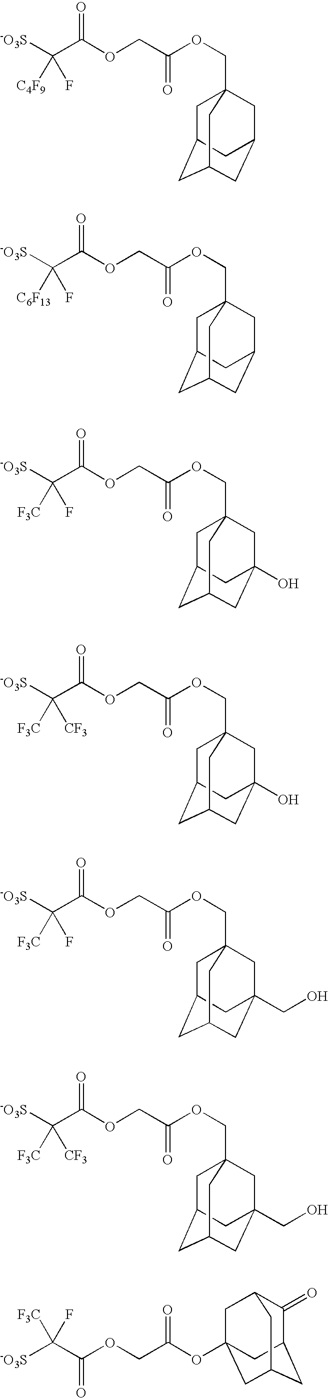

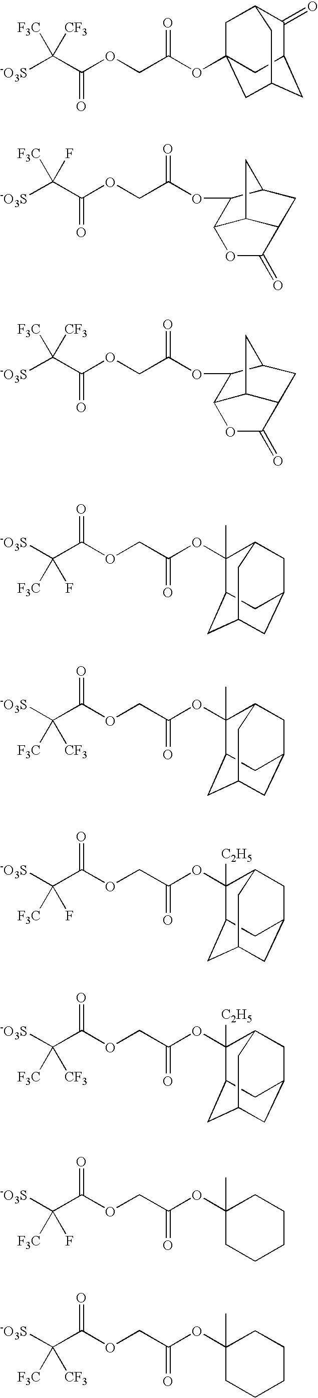

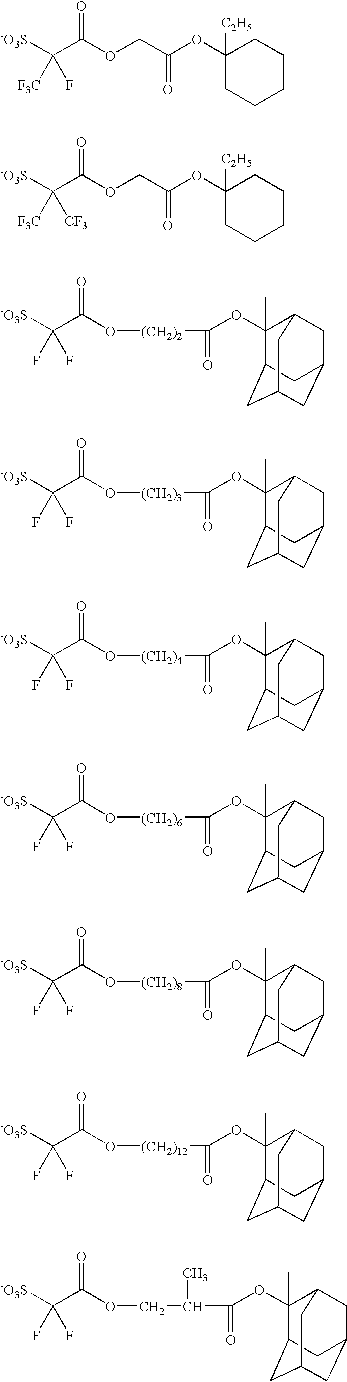

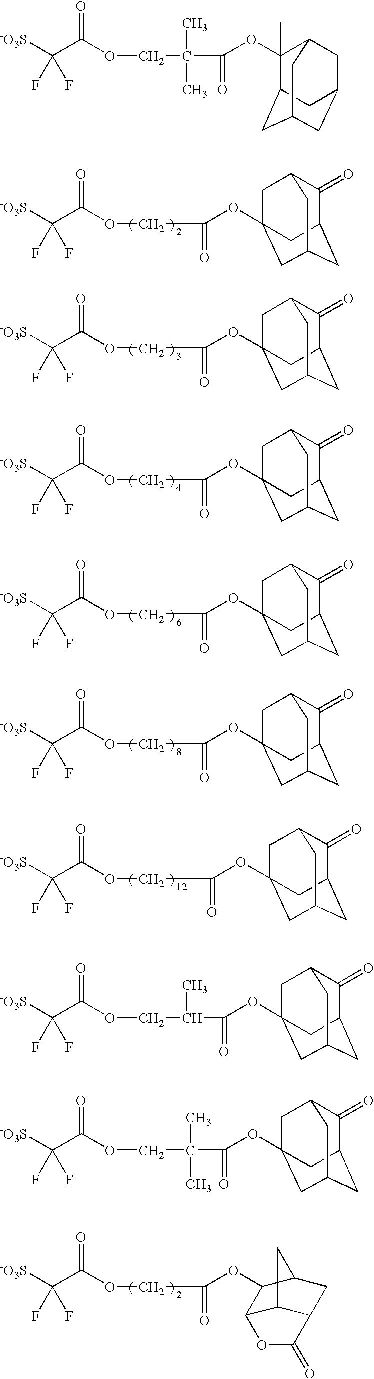

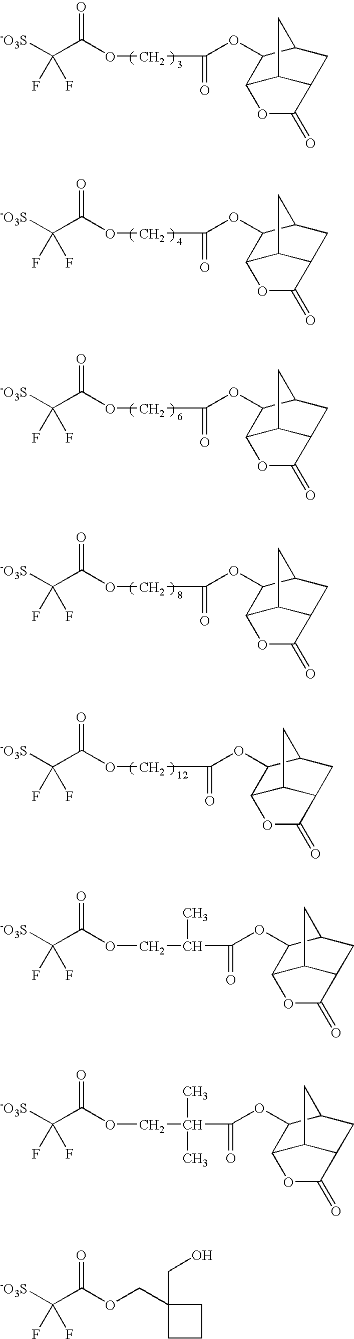

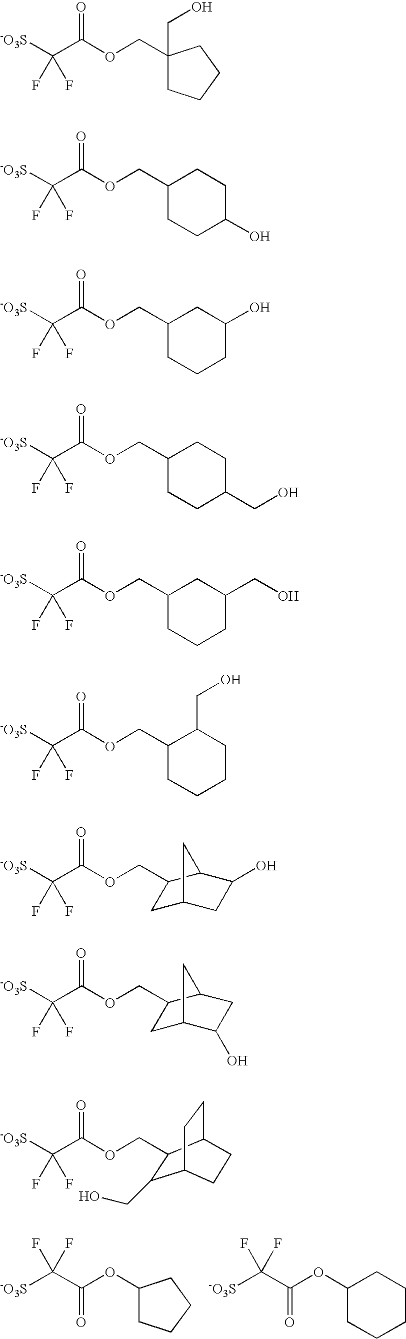

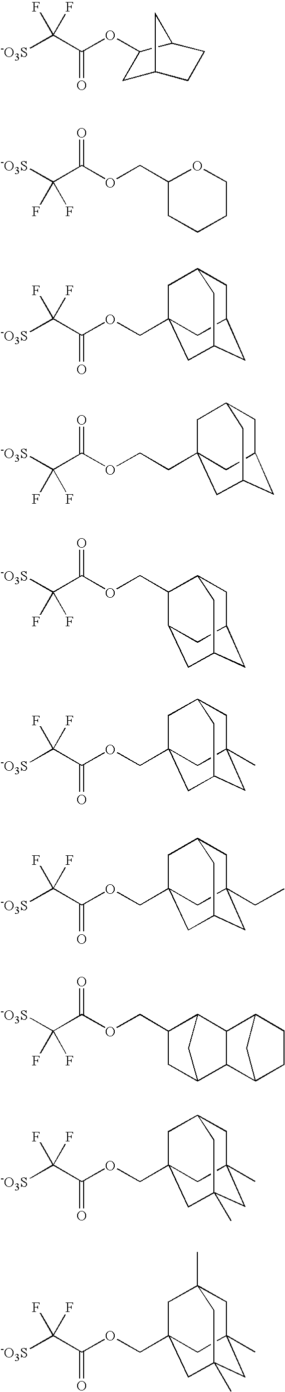

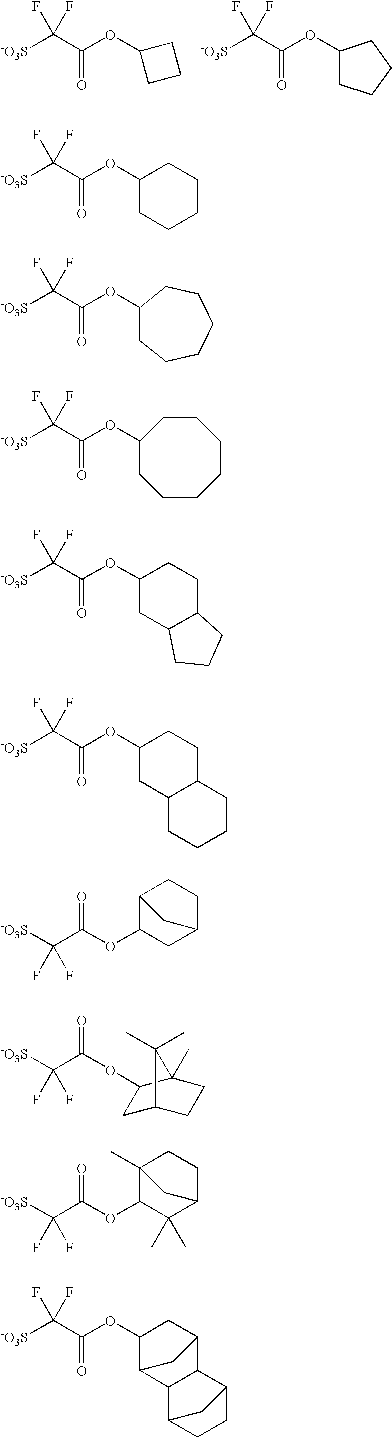

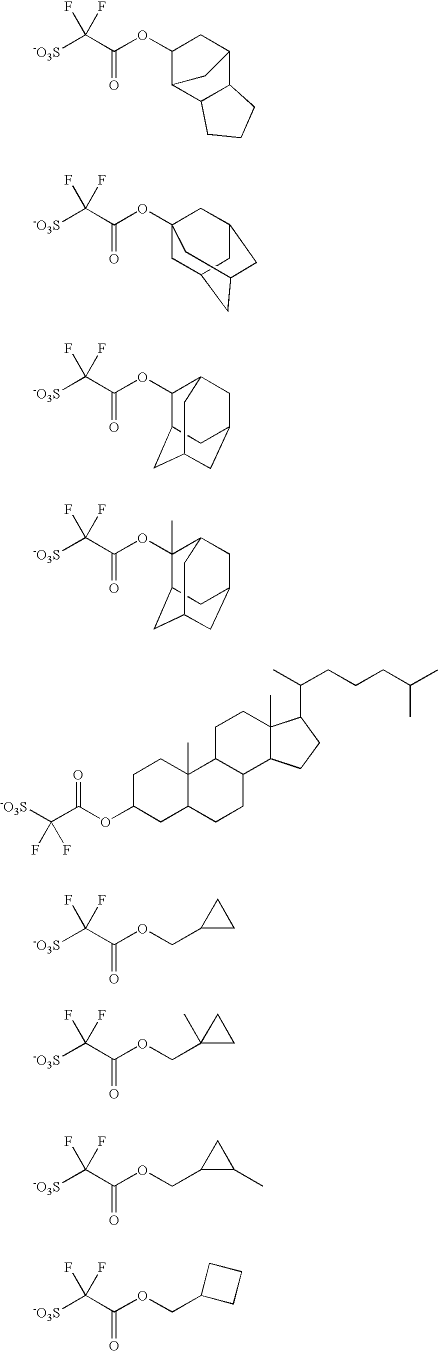

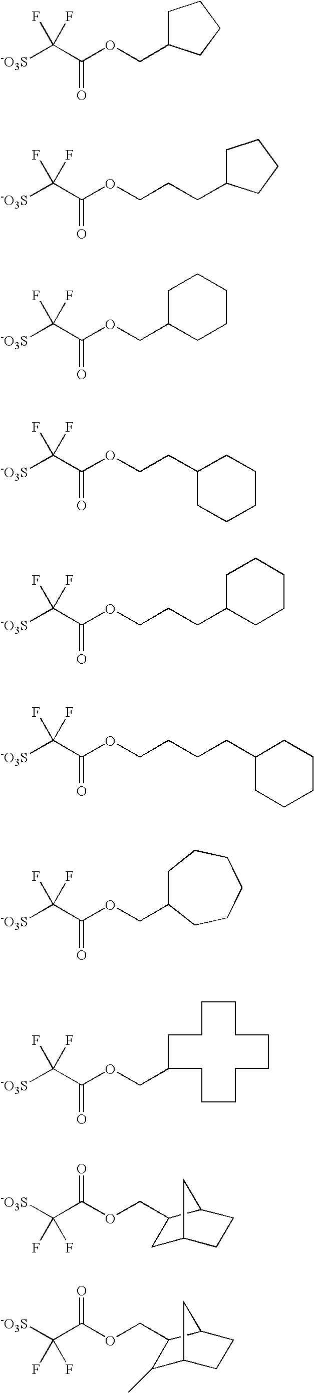

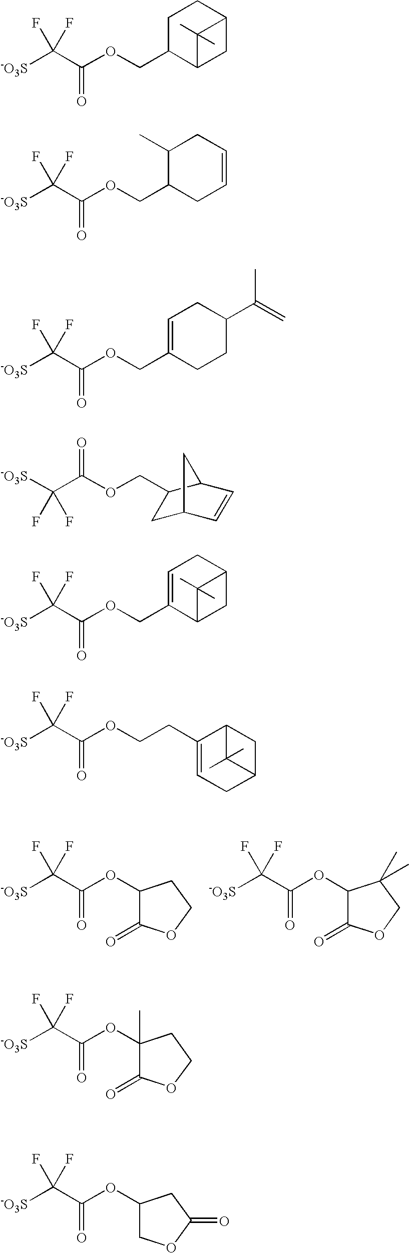

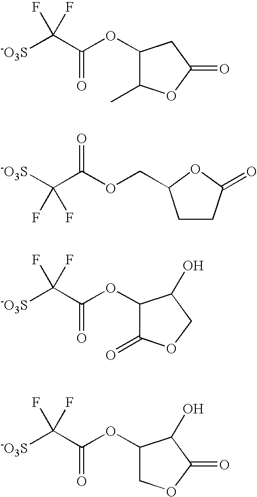

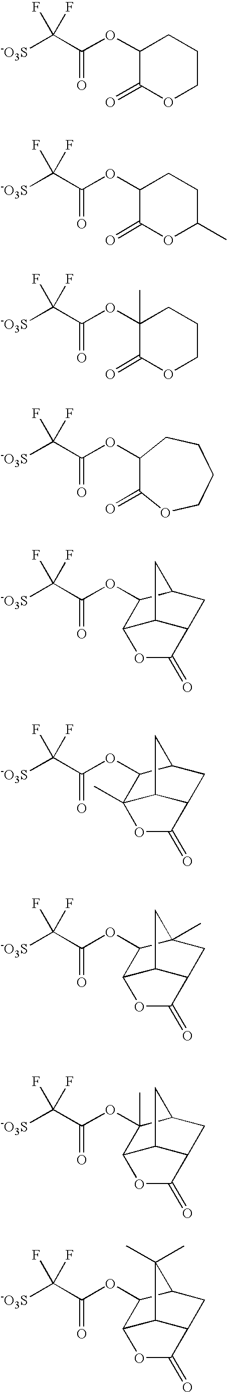

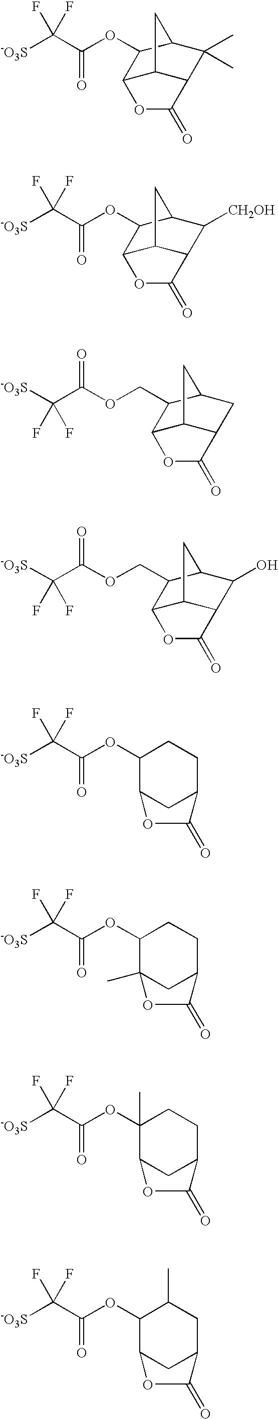

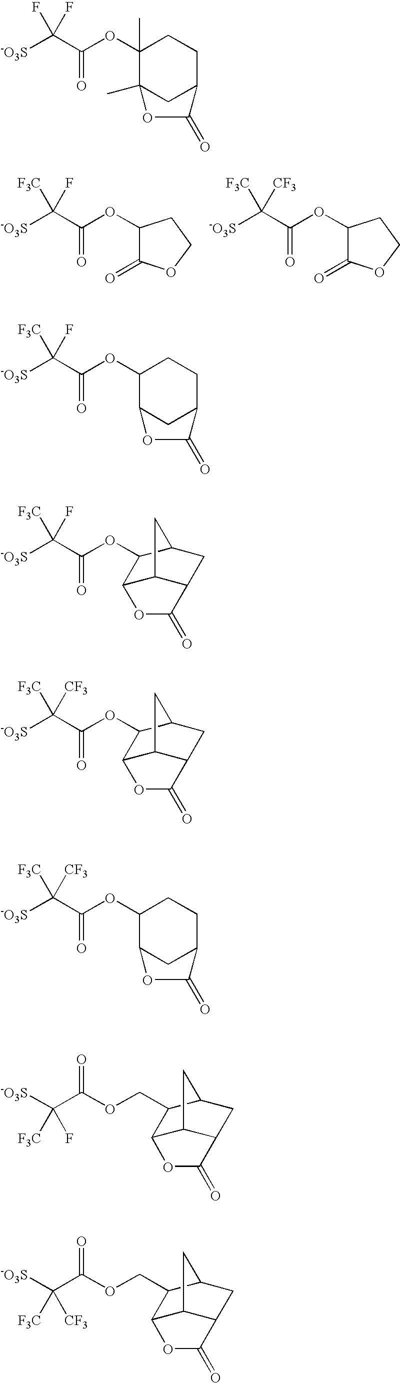

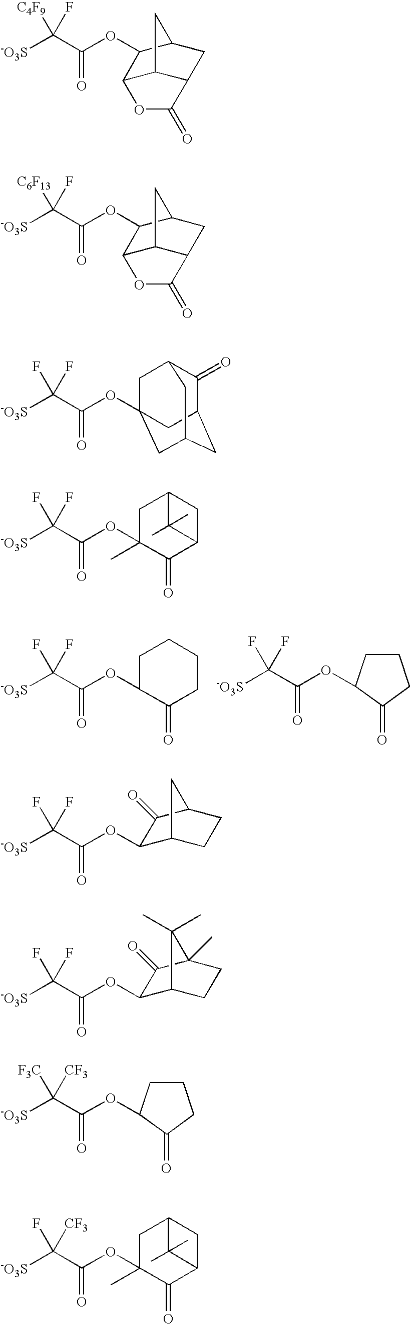

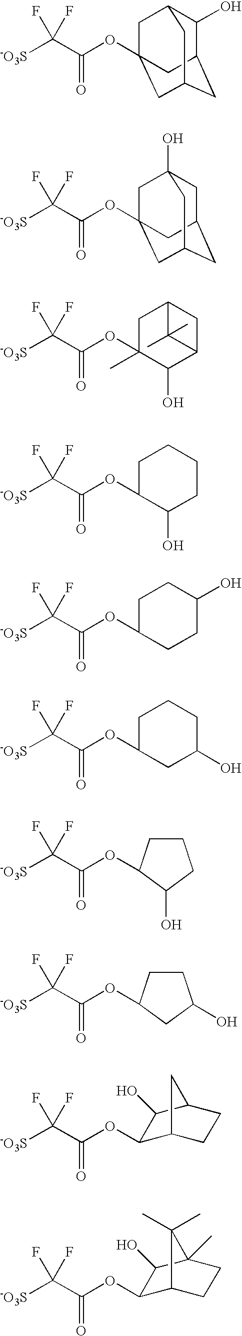

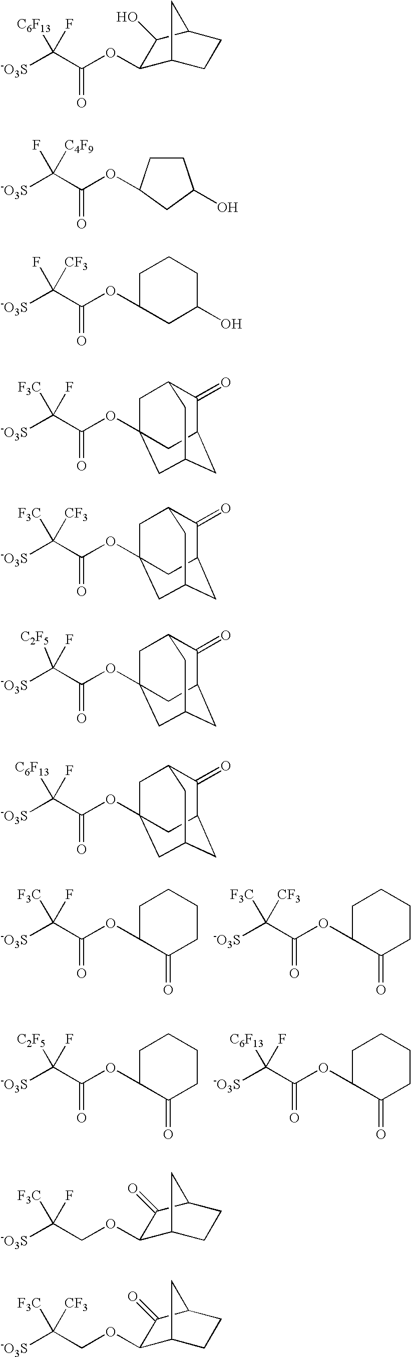

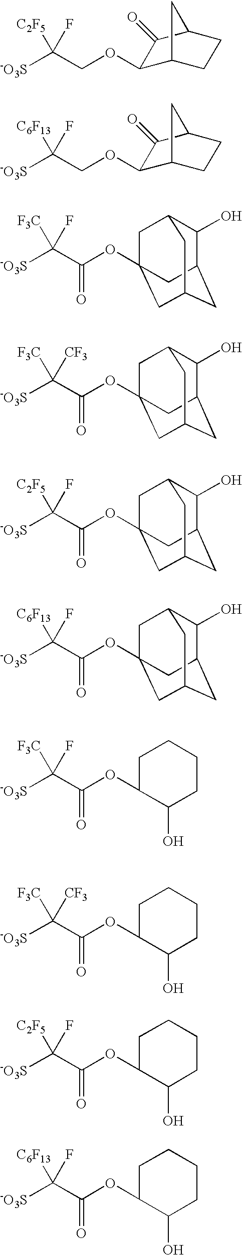

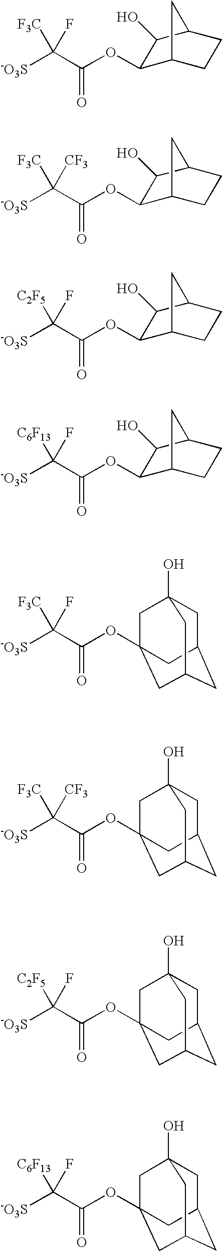

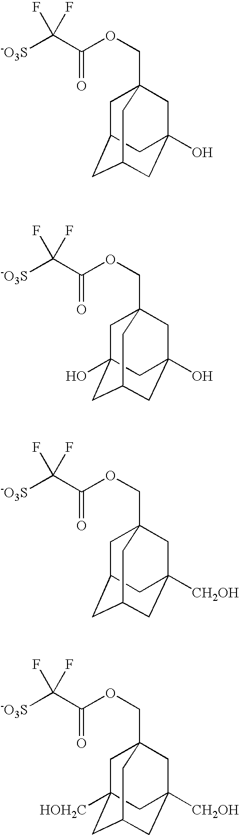

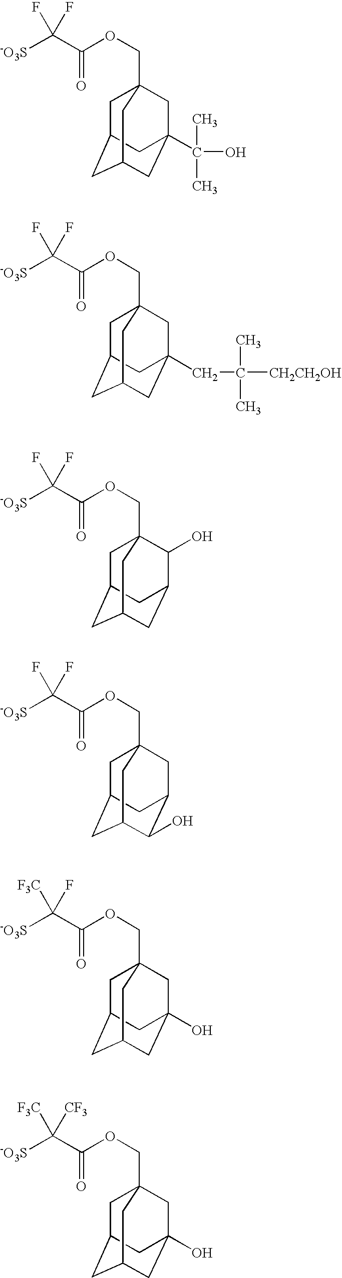

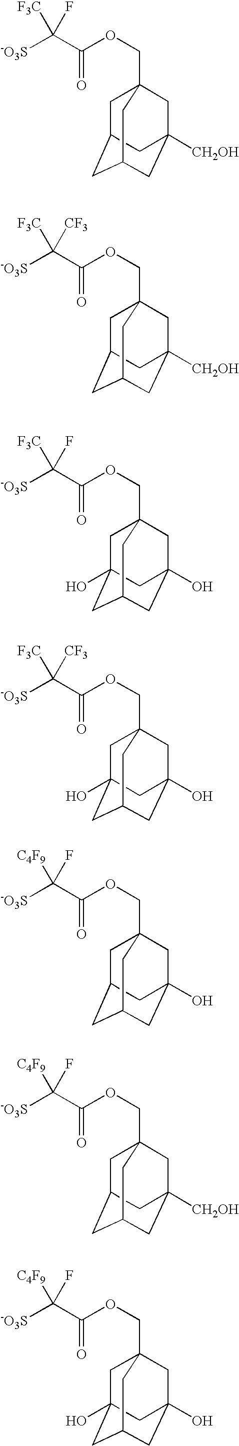

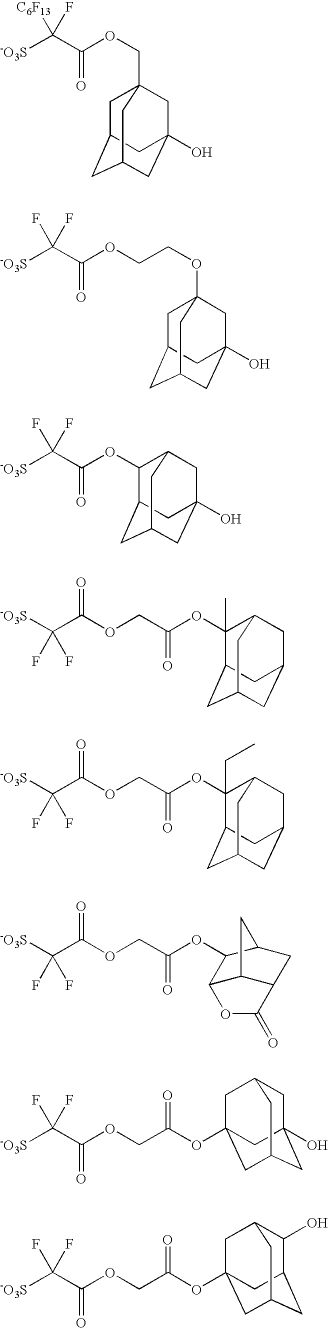

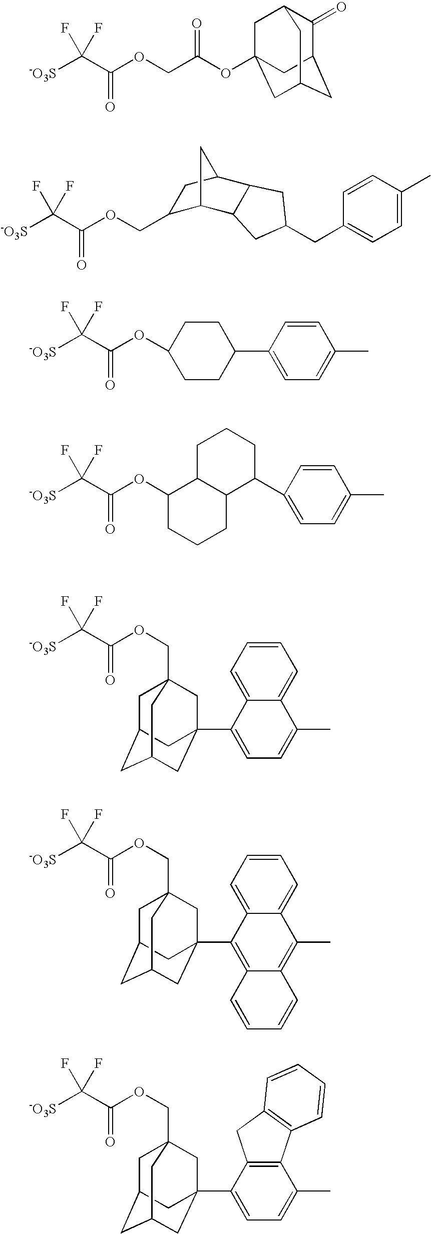

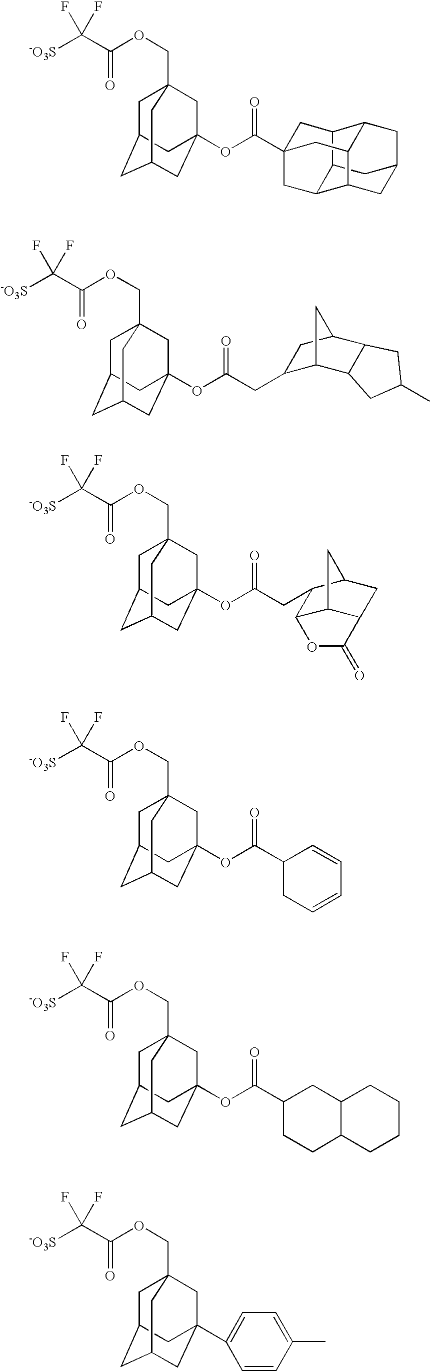

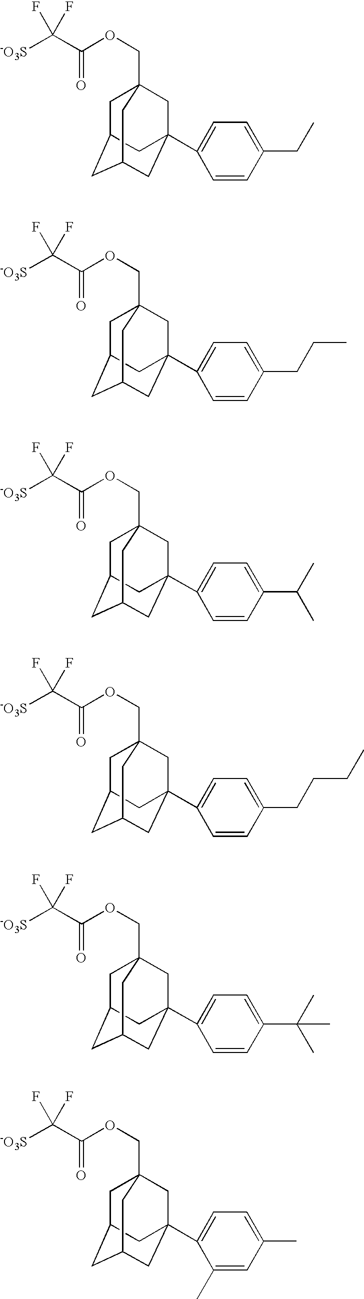

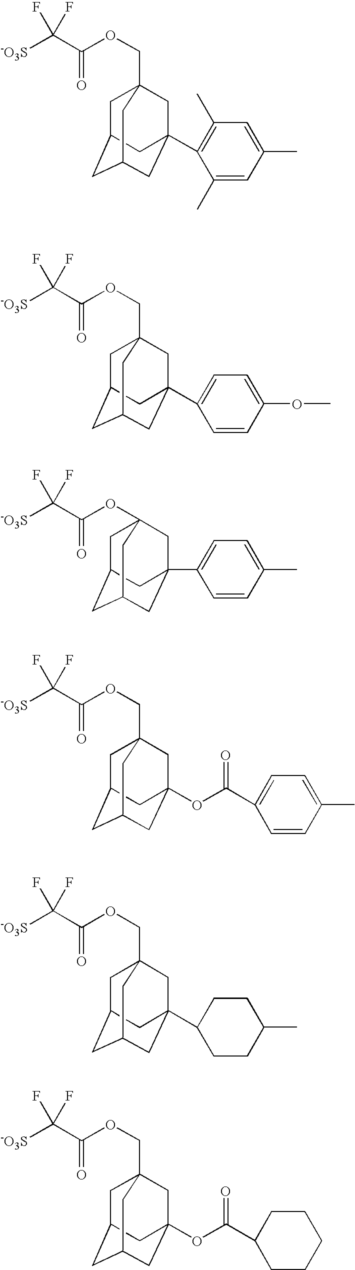

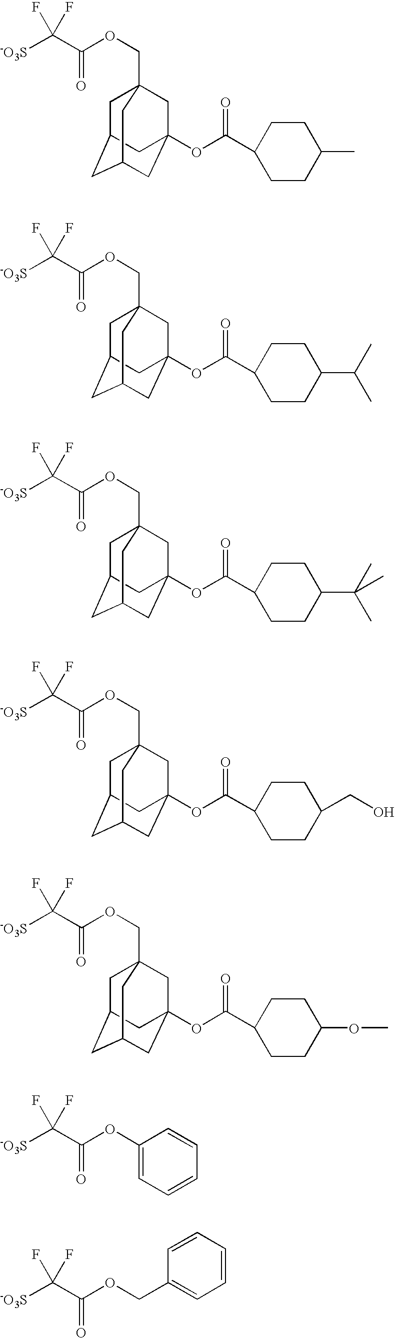

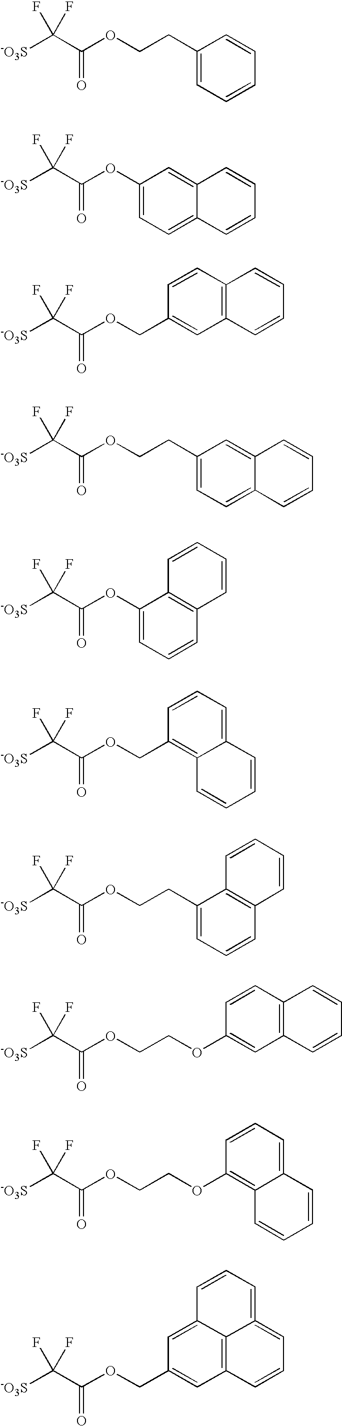

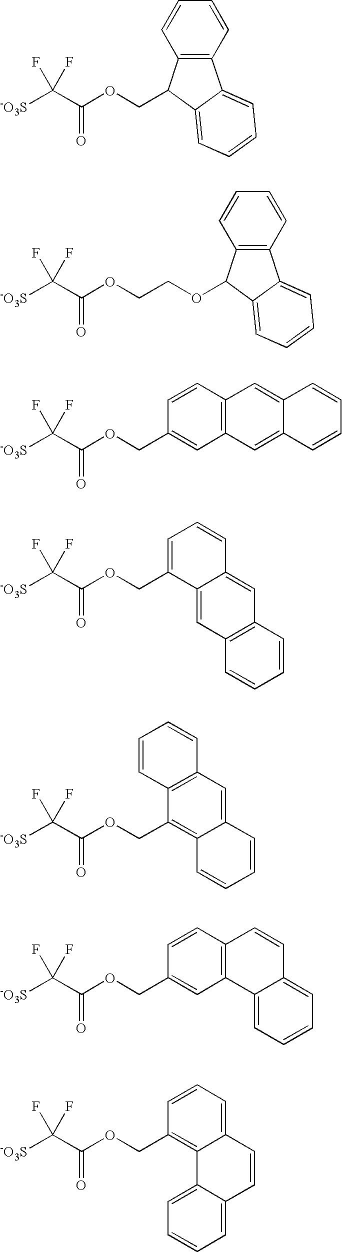

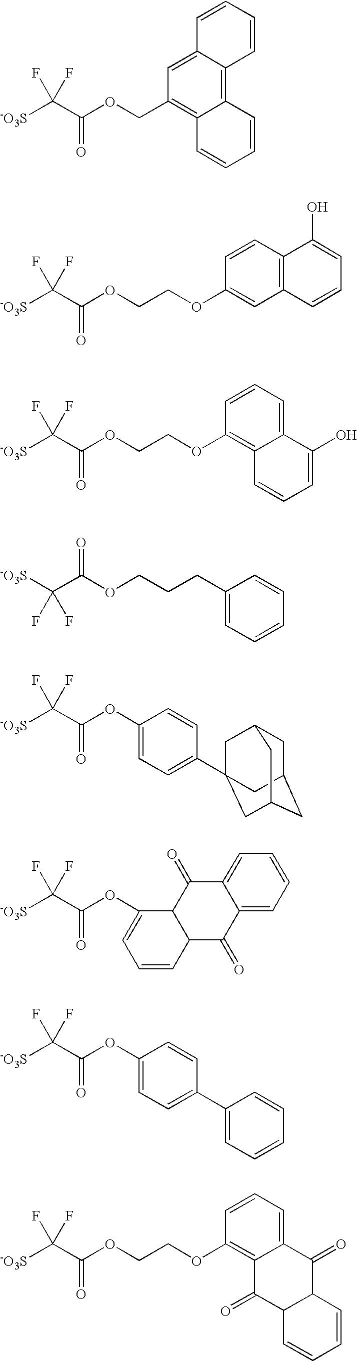

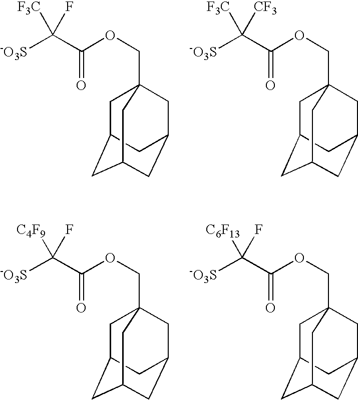

As the acid generator, a salt represented by the formula (VII):

A⁺−O₃S−R^{b} (VII)

wherein A⁺ is the same meaning as defined above, and R^{b} represents a C1-C6 alkyl group or a C1-C6 perfluoroalkyl group, and R^{b} is preferably a C1-C6 perfluoroalkyl group such as a trifluoromethyl group, a pentafluoroethyl group, a heptafluoropropyl group and a nonafluorobutyl group.

Examples of the organic counter ion include cations represented by the formulae (VIII), (IIb), (IIc) and (IId):

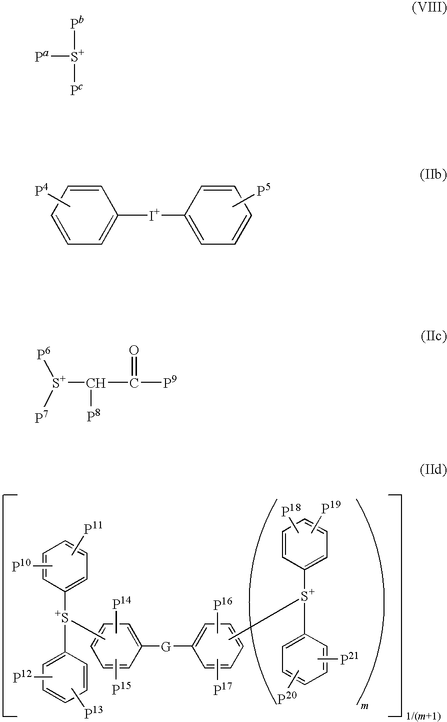

wherein P^{a}ᵣ P^{b} and P^{c} each independently represent a linear or branched chain C1-C30 alkyl group which may have one or more substituents selected from the group consisting of a hydroxyl group, a C3-C12 cyclic hydrocarbon group, a C1-C12 alkoxy group, an oxo group, a cyano group, an amino group or an amino group substituted with a C1-C4 alkyl group, or a C3-C30 cyclic hydrocarbon group which may have one or more substituents selected from the group consisting of a hydroxyl group and a C1-C12 alkoxy group, an oxo group, a cyano group, an amino group or an amino group substituted with a C1-C4 alkyl group,
P⁴ and P⁵ each independently represent a hydrogen atom, a hydroxyl group, a C1-C12 alkyl group or a C1-C12 alkoxy group, P⁶ and P⁷ each independently represent a C1-C12 alkyl group or a C3-C12 cycloalkyl group, or P⁶ and P⁷ are bonded to form a C3-C12 divalent acyclic hydrocarbon group which forms a ring together with the adjacent S⁺, and one or more —CH₂— in the divalent acyclic hydrocarbon group may be replaced by —CO—, —O— or —S—, P⁸ represents a hydrogen atom, P⁹ represents a C1-C12 alkyl group, a C3-C12 cycloalkyl group or a C6-C20 aromatic group which may have one or more substituents, or P⁸ and P⁹ are bonded each other to form a divalent acyclic hydrocarbon group which forms a 2-oxocycloalkyl group together with the adjacent —CHCO—, and one or more —CH₂— in the divalent acyclic hydrocarbon group may be replaced by —CO—, —O— or —S—, and P¹⁰,P¹¹,P¹²,P¹³,P¹⁴,P¹⁵,P¹⁶,P¹⁷,P¹⁸,P¹⁹,P²⁰ and P²¹ each independently represent a hydrogen atom, a hydroxyl group, a C1-C12 alkyl group or a C1-C12 alkoxy group, G represents a sulfur atom or an oxygen atom and m represents 0 or 1.

Examples of the C1-C12 alkoxy group in the formulae (VIII), (IIb) and (IId) include a methoxy group, an ethoxy group, a propoxy group, an isopropoxy group, a butoxy group, an isobutoxy group, a sec-butoxy group, a tert-butoxy group, a pentyloxy group, a hexyloxy group, an octyloxy group and a 2-ethylhexyloxy group. Examples of the C3-C12 cyclic hydrocarbon group in the formula (VIII) include a cyclopentyl group, a cyclohexyl group, a 1-adamantyl group, a 2-adamantyl group, a phenyl group, a 2-methylphenyl group, a 4-methylphenyl group, a 1-naphthyl group and a 2-naphthyl group.

Examples of the C1-C30 alkyl group which may have one or more substituents selected from the group consisting of a hydroxyl group, a C3-C12 cyclic hydrocarbon group, a C1-C12 alkoxy group, an oxo group, a cyano group, an amino group or an amino group substituted with a C1-C4 alkyl group in the formula (VIII) include a methyl group, an ethyl group, a propyl group, an isopropyl group, a butyl group, an isobutyl group, a sec-butyl group, a tert-butyl group, a pentyl group, a hexyl group, an octyl group, a 2-ethylhexyl group and a benzyl group.

Examples of the C3-C30 cyclic hydrocarbon group which may have one or more substituents selected from the group consisting of a hydroxyl group, a C1-C12 alkoxy group, an oxo group, a cyano group, an amino group or an amino group substituted with a C1-C4 alkyl group in the formula (VIII) include a cyclopentyl group, a cyclohexyl group, a 1-adamantyl group, a 2-adamantyl group, a bicyclohexyl group, a phenyl group, a 2-methylphenyl group, a 4-methylphenyl group, a 4-ethylphenyl group, a 4-isopropylphenyl group, a 4-tert-butylphenyl group, a 2,4-dimethylphenyl group, a 2,4,6-trimethylphenyl group, a 4-hexylphenyl group, a 4-octylphenyl group, a 1-naphthyl group, a 2-naphthyl group, a fluorenyl group, a 4-phenylphenyl group, a 4-hydroxyphenyl group, a 4-methoxyphenyl group, a 4-tert-butoxyphenyl group and a 4-hexyloxyphenyl group.

Examples of the C1-C12 alkyl group in the formulae (IIb), (IIc) and (IId) include a methyl group, an ethyl group, a propyl group, an isopropyl group, a butyl group, an isobutyl group, a sec-butyl group, a tert-butyl group, a pentyl group, a hexyl group, an octyl group and a 2-ethylhexyl group.

Examples of the C3-C12 cycloalkyl group in the formula (IIc) include a cyclopropyl group, a cyclobutyl group, a cyclopentyl group, a cyclohexyl group, a cycloheptyl group, a cyclooctyl group and a cyclodecyl group. Examples of the C3-C12 divalent acyclic hydrocarbon group formed by bonding P⁶ and P⁷ include a trimethylene group, a tetramethylene group and a pentamethylene group. Examples of the ring group formed together with the adjacent S⁺ and the divalent acyclic hydrocarbon group include a tetramethylenesulfonio group, a pentamethylenesulfonio group and an oxybisethylenesulfonio group.

Examples of the C6-C20 aromatic group which may have one or more substituents in the formula (IIc) include a phenyl group, a tolyl group, a xylyl group, a tert-butylphenyl group and a naphthyl group. Examples of the divalent acyclic hydrocarbon group formed by bonding P⁸ and P⁹ include a methylene group, an ethylene group, a trimethylene group, a tetramethylene group and a pentamethylene group and examples of the 2-oxocycloalkyl group formed together with the adjacent —CHCO— and the divalent acyclic hydrocarbon group include a 2-oxocyclopentyl group and a 2-oxocyclohexyl group.

The cation represented by the formula (VIII) is preferable and a cation represented by the formula (IIa):

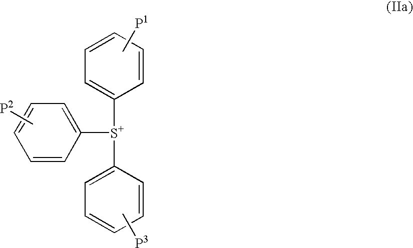

wherein P¹, P² and P³ are independently in each occurrence a hydrogen atom, a hydroxyl group, a C1-C12 alkyl group, a C1-C12 alkoxy group, a cyano group or an amino group which may be substituted with a C1-C4 alkyl group, is preferable, and a cation represented by the formula (IIe):

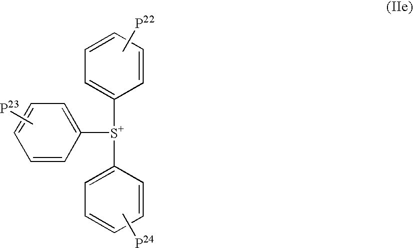

wherein P²², P²³ and P²⁴ are independently in each occurrence a hydrogen atom, a hydroxyl group or a C1-C12 alkyl group, is more preferable, and a cation represented by the formula (IIf):

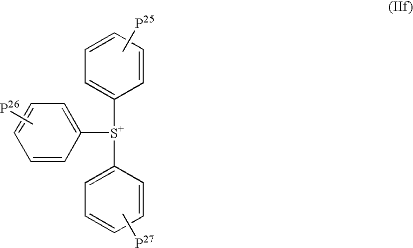

wherein P²⁵, P²⁶ and P²⁷ are independently in each occurrence a hydrogen atom, a hydroxyl group or a C1-C4 alkyl group, is also more preferable.

In the formula (IIa), examples of the halogen atom include a fluorine atom, a chlorine atom, a bromine atom and an iodine atom, and a fluorine atom, a chlorine atom and a bromine atom are preferable, and a fluorine atom is more preferable. Examples of the C1-C12 alkyl group include a methyl group, an ethyl group, a propyl group, an isopropyl group, a butyl group, an isobutyl group, a sec-butyl group, a tert-butyl group, a pentyl group, a hexyl group, an octyl group and a 2-ethylhexyl group. Examples of the C1-C12 alkoxy group include a methoxy group, an ethoxy group, a propoxy group, a butoxy group, a hexyloxy group, an octyloxy group and a 2-ethylhexyloxy group. Examples of the C3-C12 cyclic hydrocarbon group, and the C3-C12 cyclic hydrocarbon group may have a halogen atom, a hydroxyl group or a C1-C12 alkoxy group include a group having an adamantyl skeleton and a group having an isobornyl skeleton, and preferable examples thereof include a 2-alkyl-2-adamantyl group, a 1-(1-adamantyl)-1-alkyl group and an isobornyl group.

Examples of the cations represented by the formulae (IIa), (IIe) and (IIf) include the followings.

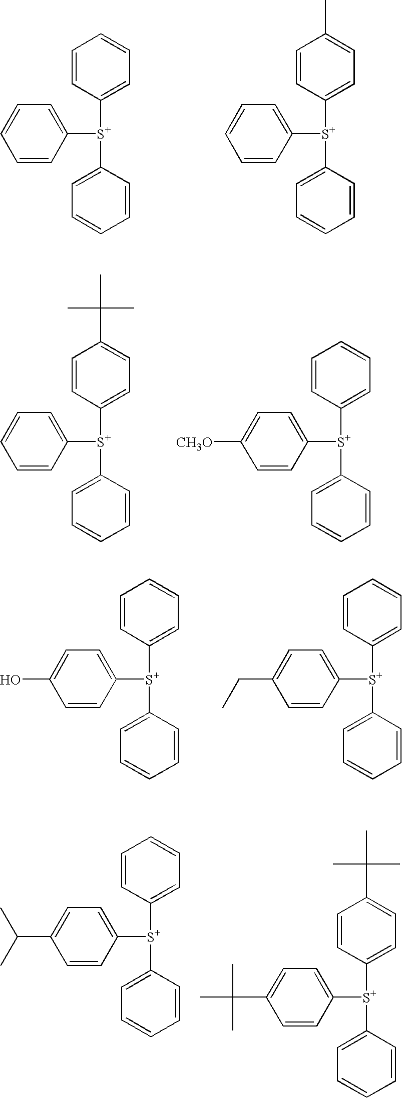

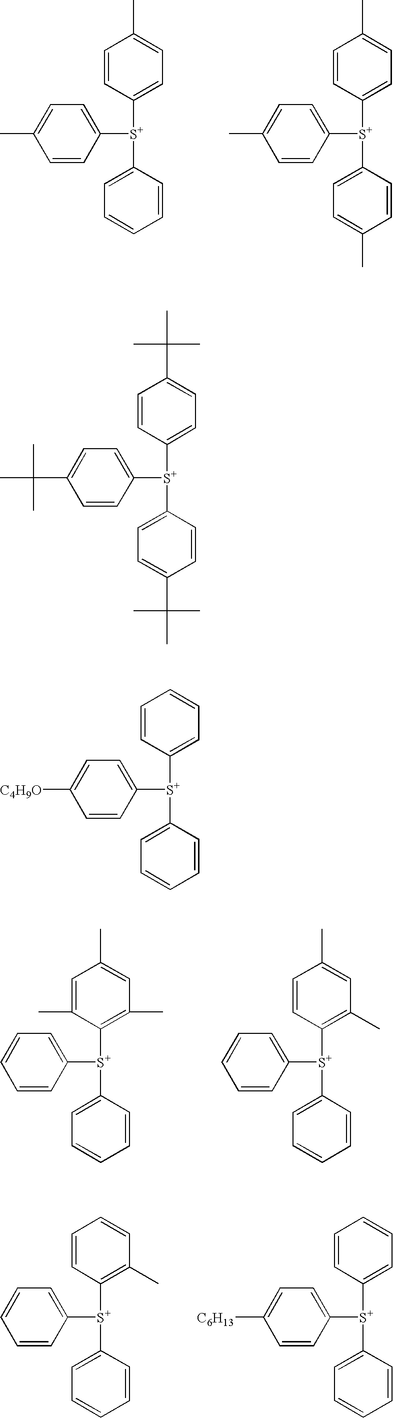

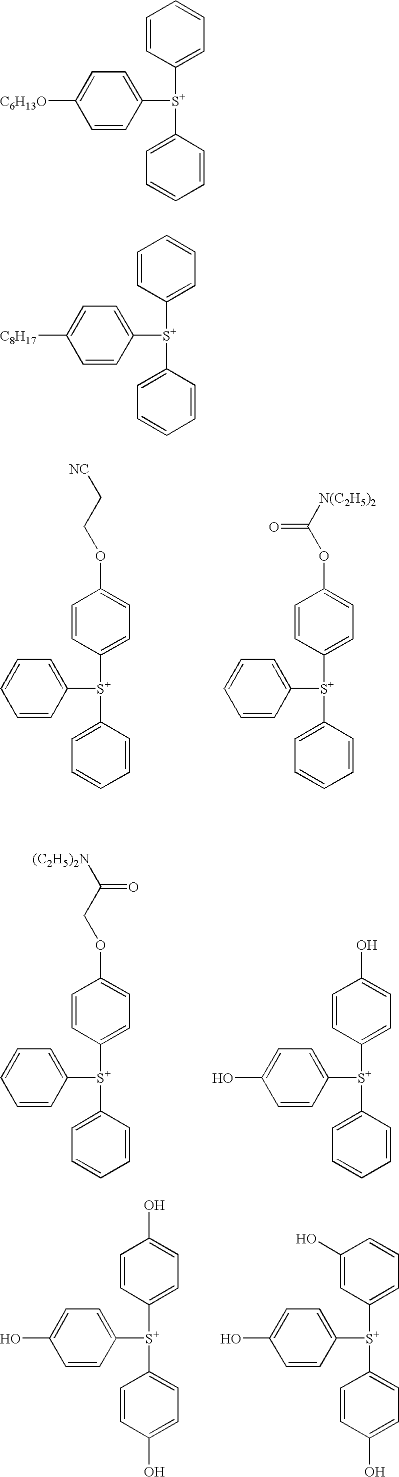

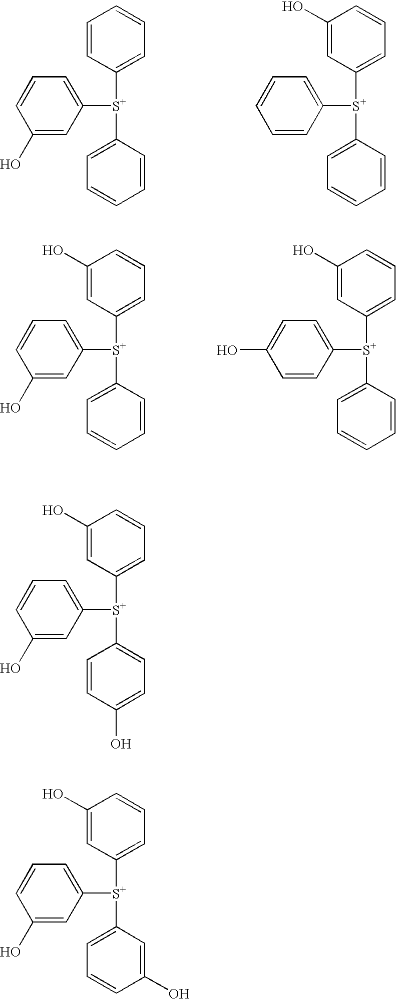

Examples of the cation represented by the formula (IIb) include the followings.

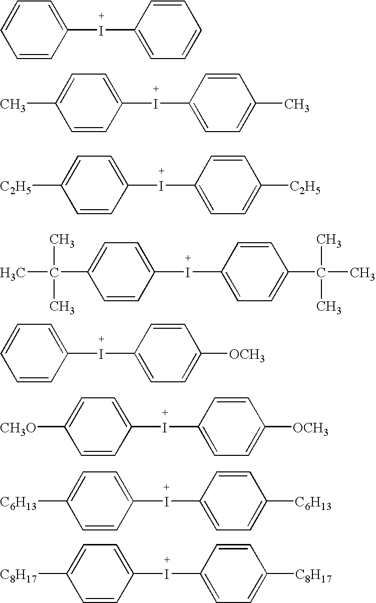

Examples of the cation represented by the formula (IIc) include the followings.

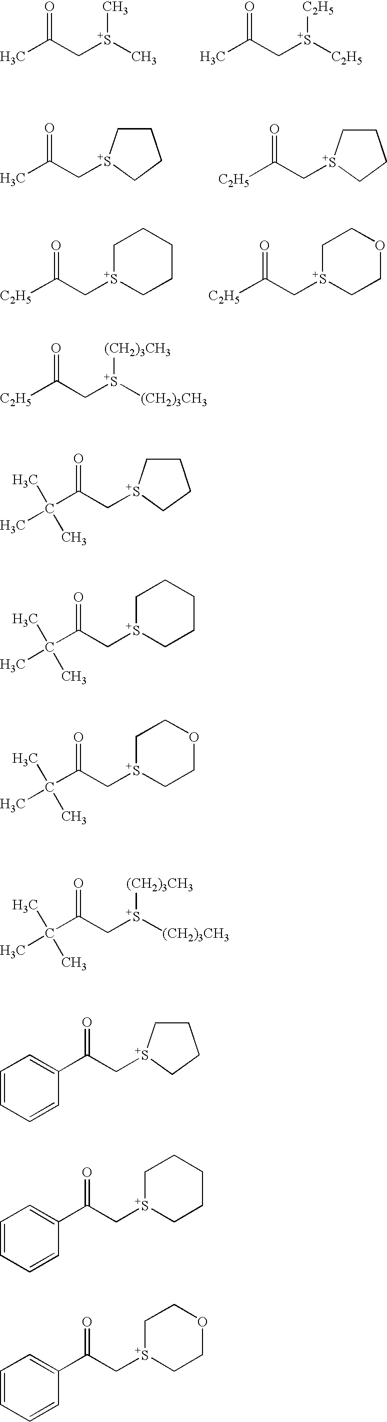

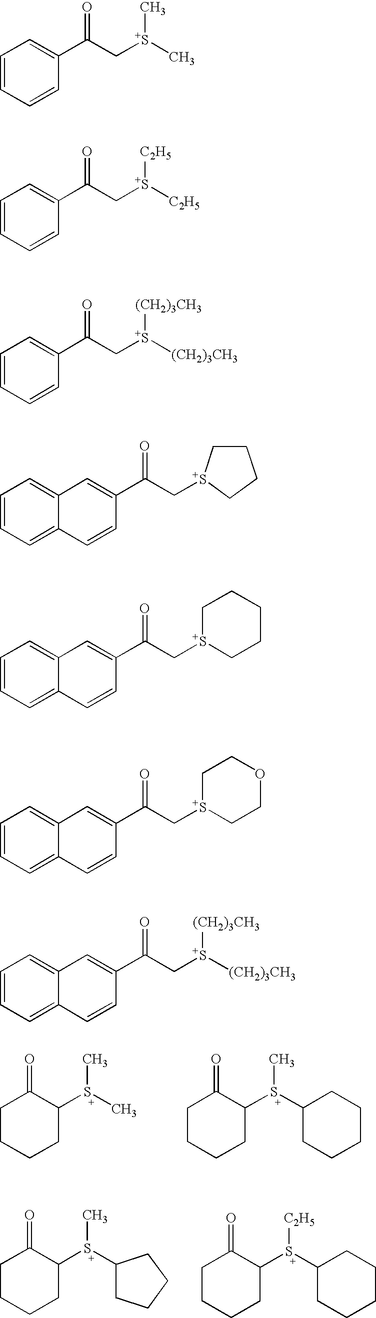

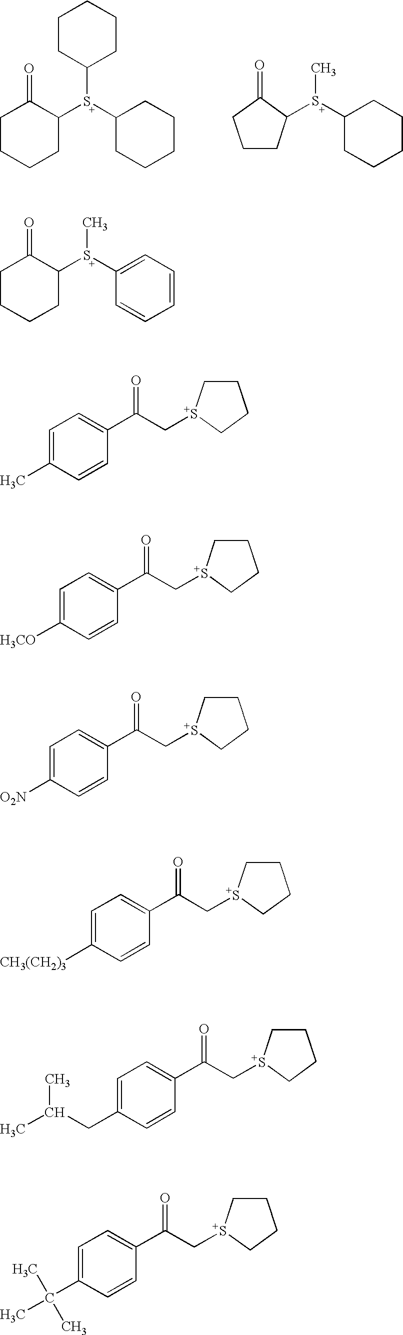

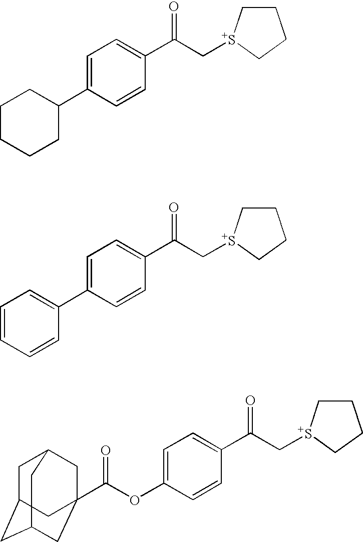

Examples of the cation represented by the formula (IId) include the followings.

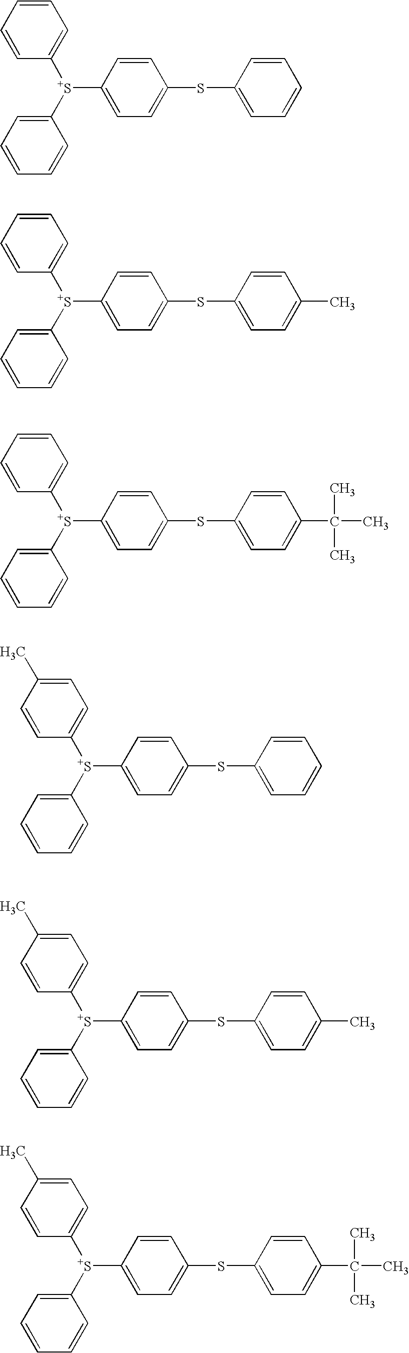

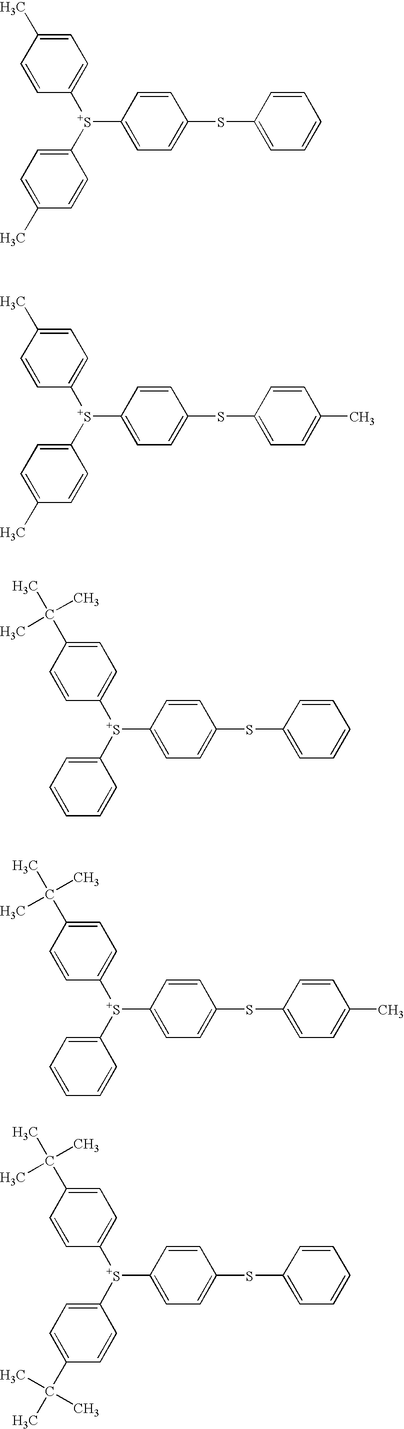

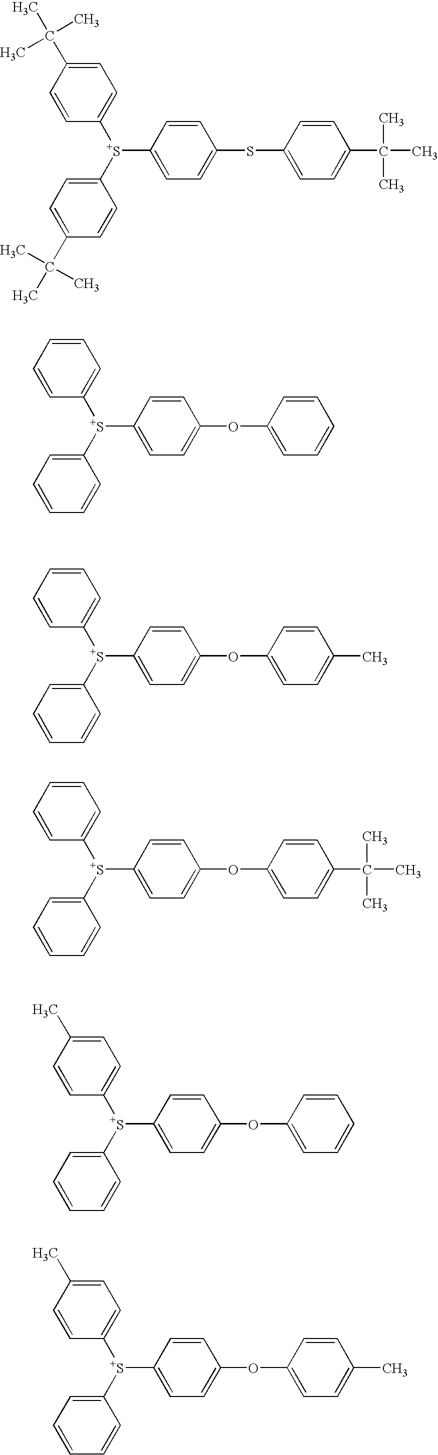

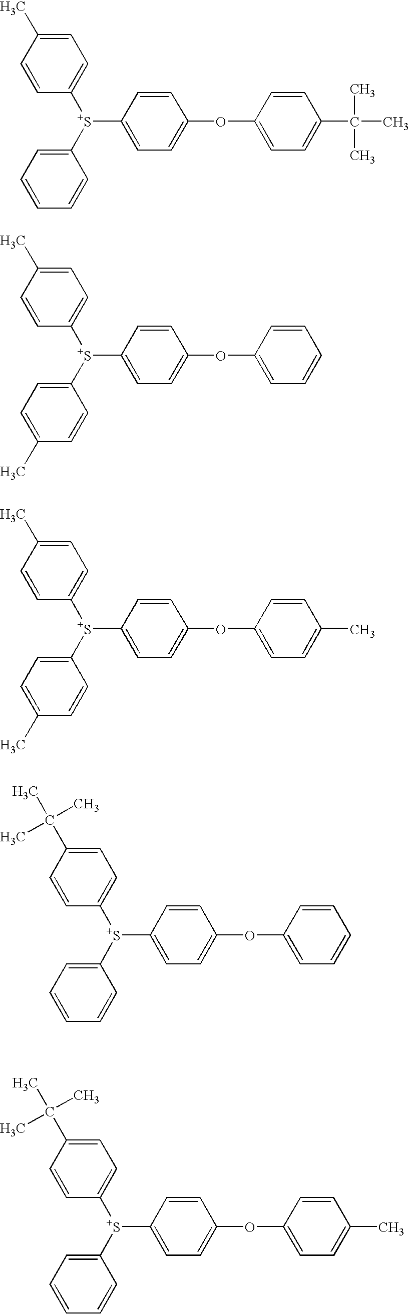

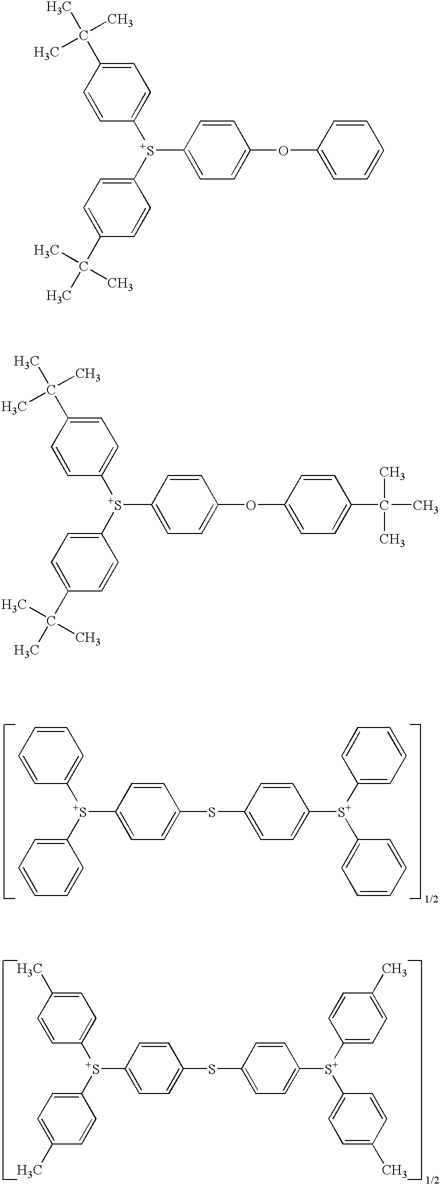

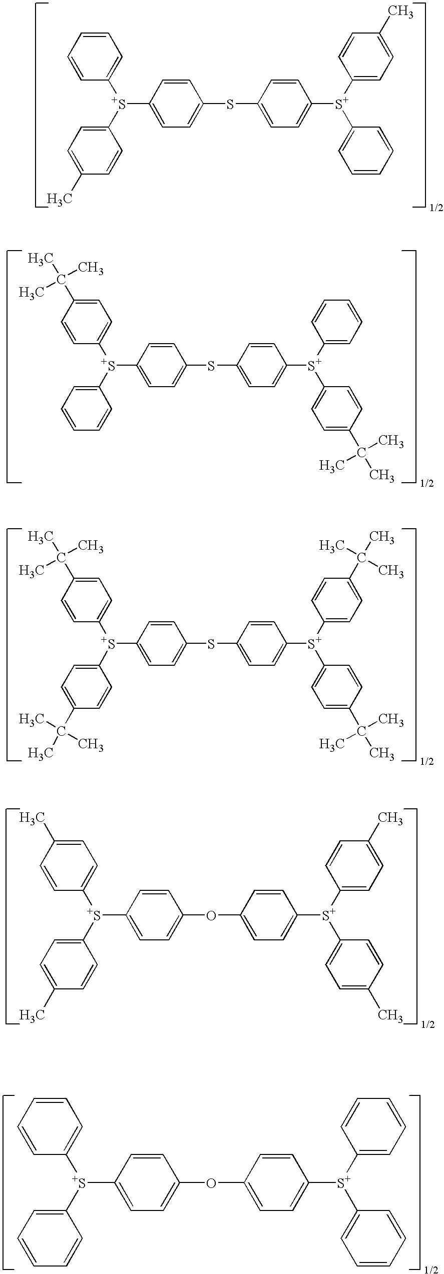

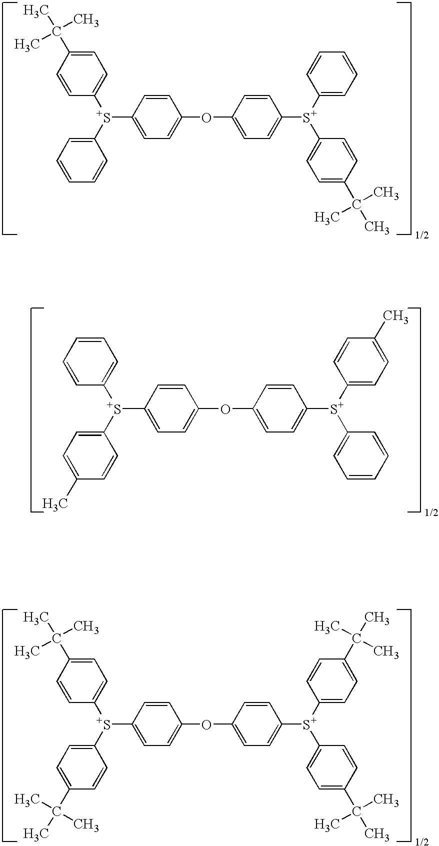

From the viewpoint of resolution of the photoresist composition and pattern profile obtained, salts represented by the formulae (IXa), (IXb), (IXc), (IXd) and (IXe):

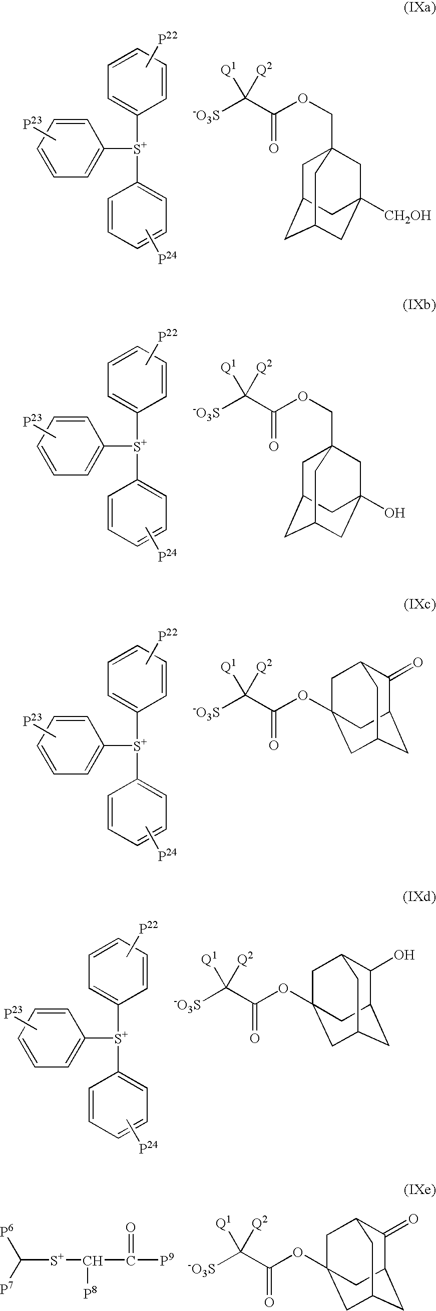

wherein P⁶, P⁷, P⁸, P⁹, P²², P²³, P²⁴, P²⁵, P²⁶, P²⁷, Q¹ and Q² are the same meanings as defined above, are preferable as the acid generator.

Among them, the following salts are more preferable because of easy production thereof.

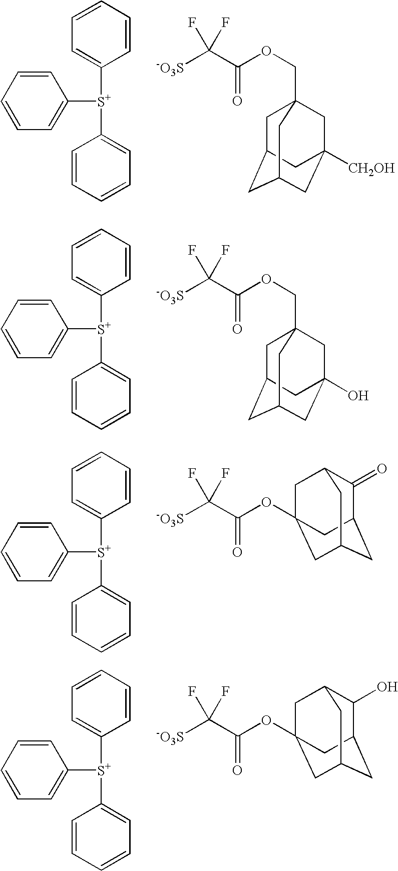

These salts used as the acid generator can be produced according to the method described in JP 2006-257078 A.

The salts represented by the formula (V) and (VI) can be also produced by reacting a compound represented by the formula (1) or (2):

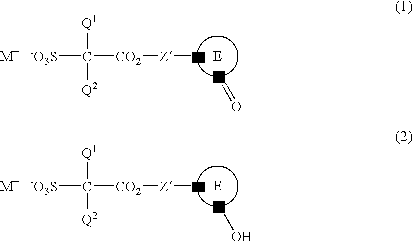

wherein Q¹, Q², Z′ and ring E are the same meanings as defined above, and M⁺ represents Li⁺, Na⁺ or K⁺, with a compound represented by the formula (3):

A⁺Z⁻ (3)

wherein A⁺ is the same meaning as defined above and Z⁻ represents F−, Cl⁻, Br⁻, I⁻, BF₄⁻, AsF₆⁻, SbF₆⁻, PF₆⁻ or ClO₄⁻, in an inert solvent such as water, acetonitrile and methanol, with stirring at a temperature of 0 to 150° C. and preferably of 0 to 100° C.

The amount of the compound represented by the formula (3) to be used is usually 0.5 to 2 moles per 1 mole of the compound represented by the formula (1) or (2). The salt represented by the formula (1) or (2) obtained may be taken out by crystallization or washing with water.

The compounds represented by the formulae (1) and (2) can be produced by esterifying an alcohol compound of the formula (4) or (5):

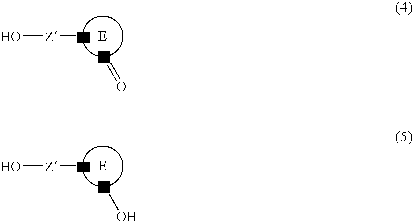

wherein Z′ and ring E are the same meanings as defined above, with a carboxylic acid compound of the formula (6):

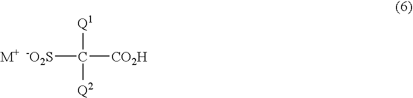

wherein M⁺, Q¹ and Q² are the same meanings as defined above.

The esterification reaction can generally be carried out by mixing materials in an aprotic solvent such as dichloroethane, toluene, ethylbenzene, monochlorobenzene and acetonitrile, with stirring, at 20 to 200° C., preferably 50 to 150° C. In the esterification reaction, an acid catalyst is usually added, and examples of the acid catalyst include organic acids such as p-toluenesulfonic acid, and inorganic acids such as sulfuric acid.

The esterification reaction is preferably carried out with dehydration, for example, by Dean and Stark method as the reaction time tends to be shortened.

The amount of the carboxylic acid compound of the formula (6) is usually 0.2 to 3 moles, and preferably 0.5 to 2 moles per 1 mol of the alcohol compound of the formula (4) or (5). The amount of the acid catalyst maybe catalytic amount or the amount equivalent to solvent, and is usually 0.001 to 5 moles per 1 mol of the alcohol compound of the formula (4) or (5).

Alternatively, the compounds represented by the formulae (1) and (2) can be produced by esterifying the alcohol compound of the formula (4) or (5) with a carboxylic acid compound represented by the formula (7):

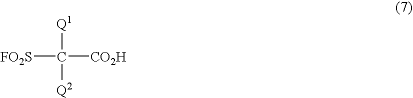

wherein Q¹ and Q² are the same meanings as defined above, followed by hydrolyzing the obtained compound with MOH wherein M represents Li, Na or K.

Additionally, the salt represented by the formula (VI) can be produced by reducing the salt represented by the formula (V), and the compound represented by the formula (2) can be produced by reducing the compound represented by the formula (1). The reduction reaction is usually conducted in a solvent such as water, alcohol, acetonitrile, N,N-dimethylformamide, diglyme, tetrahydrofuran, diethyl ether, dichloromethane, 1,2-dimethoxyethane and benzene, and the reducing agent such as a borohydride compound such as sodium borohydride, zinc borohydride, lithium tri(sec-butyl) borohydride, and borane, an aluminum hydride compound such as lithium tri(tert-butoxy)aluminum hydride and diisobutylaluminum hydride, an organic hydrosilane compound such as triethylsilane and diphenylsilane, and an organic tin hydride compound such as tributyltin. The reduction reaction is usually carried out at −80 to 100° C. and preferably −10 to 60° C.

As the acid generator, the salts represented by the formulae (X-1), (X-2), (X-3) and (X-4):

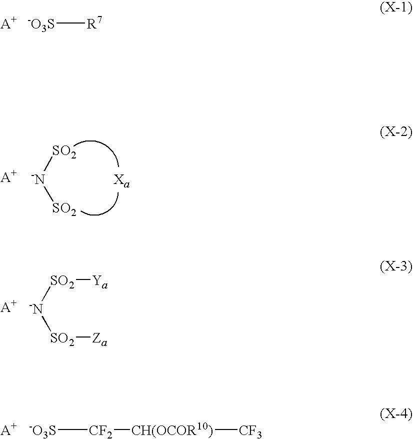

wherein R⁷ represents an alkyl group, a cycloalkyl group or a fluorinated alkyl group, Xₐ represents a C2-C6 fluorinated alkylene group, Yₐ and Zₐ independently each represent a C1-C10 fluorinated alkyl group, and R¹⁰ represents an optionally substituted C1-C20 alkyl group or an optionally substituted C6-C14 aryl group, can also be used.

In R⁷, the alkyl group preferably has 1 to 10 carbon atoms, more preferably 1 to 8 carbon atoms and especially preferably 1 to 4 carbon atoms. The cycloalkyl group preferably has 4 to 15 carbon atoms, more preferably 4 to 12 carbon atoms, much more preferably 4 to 10, and especially preferably 6 to 10 carbon atoms. The fluorinated alkyl group preferably has 1 to 10 carbon atoms, more preferably 1 to 8 carbon atoms and especially preferably 1 to 4 carbon atoms. The ratio of number of fluorine atom to total number of fluorine atoms and hydrogen atoms in the fluorinated alkyl group is preferably 10% or more, and more preferably 50% or more, and perfluoroalkyl group is especially preferable.

R⁷ is preferably a linear alkyl group, a cycloalkyl group or a fluorinated alkyl group.

Xₐ is preferably a C3-C5 fluorinated alkylene group and more preferably a C3 fluorinated alkylene group. The ratio of number of fluorine atom to total number of fluorine atoms and hydrogen atoms in the fluorinated alkylene group is preferably 70% or more, and more preferably 90% or more, and perfluoroalkylene group is especially preferable.

It is preferred that Yₐ and Zₐ are independently a C1-C7 fluorinated alkyl group, and it is more preferred that Yₐ and Zₐ are independently a C1-C3 fluorinated alkyl group. The ratio of number of fluorine atom to total number of fluorine atoms and hydrogen atoms in the fluorinated alkyl group is preferably 70% or more, and more preferably 90% or more, and perfluoroalkyl group is especially preferable.

Examples of the aryl group include a phenyl group, a tolyl group, a xylyl group, a cumyl group, a mesityl group, a naphthyl group, a biphenyl group, an anthryl group and a phenathryl group. Examples of the substituent of the alkyl group and the aryl group include a hydroxyl group, a C1-C12 alkyl group, a C1-C12 alkoxy group, a carbonyl group, —O—, —C—O—, a cyano group, an amino group, a C1-C4 alkyl substituted amino group and an amide group.

Among the salts represented by the formulae (X-1), (X-2), (X-3) and (X-4), the salt represented by the formula (X-1) is preferable and the salt represented by the formula (X-1) wherein R⁷ is a fluorinated alkyl group is more preferable.

Examples thereof include the followings.

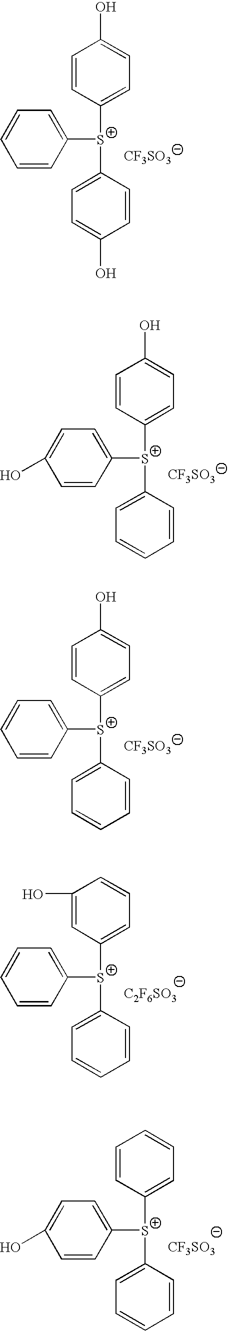

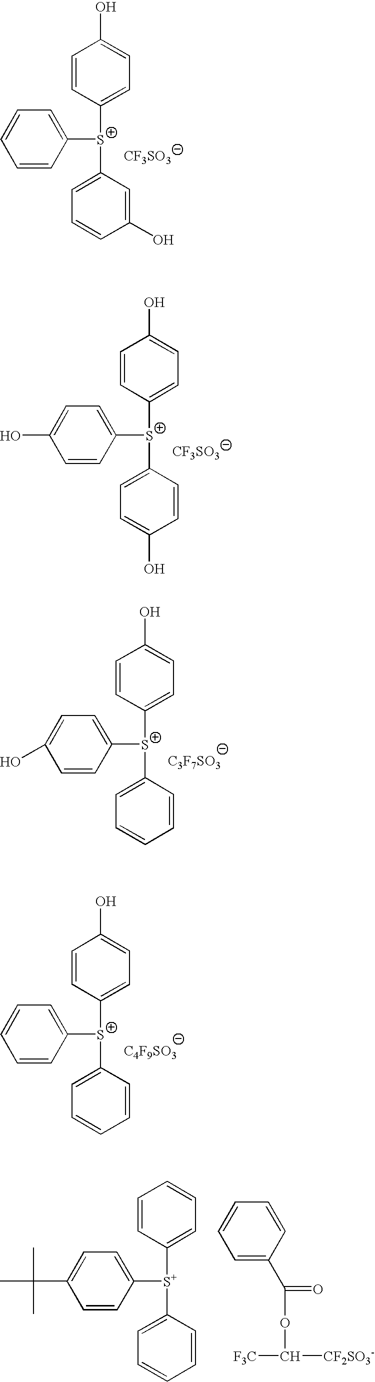

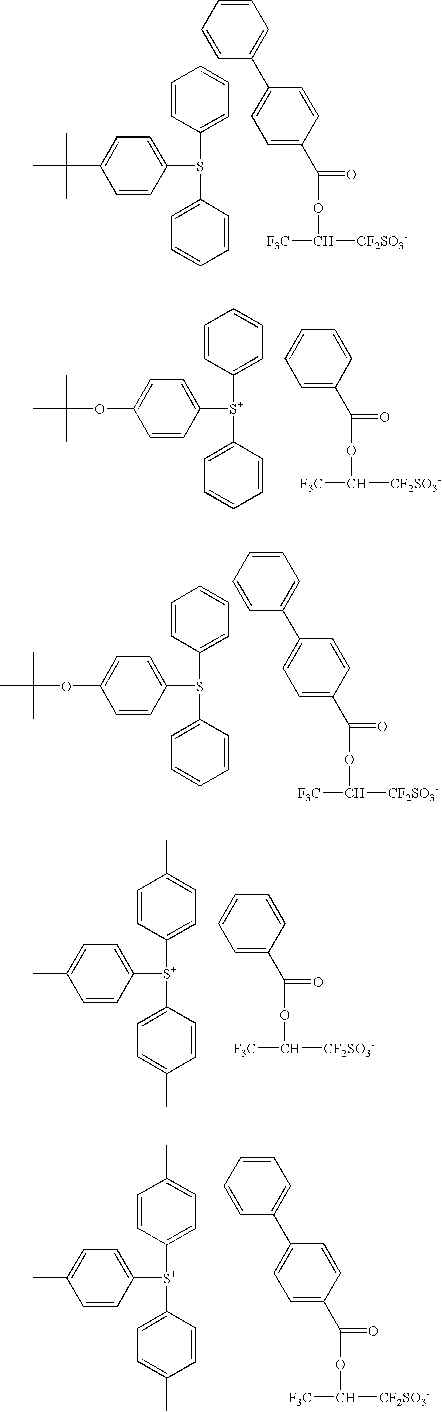

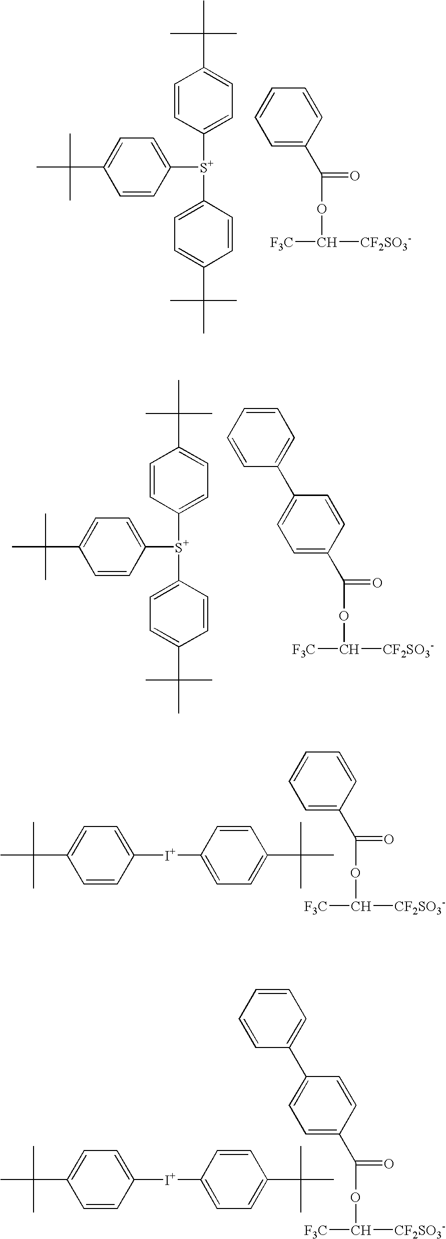

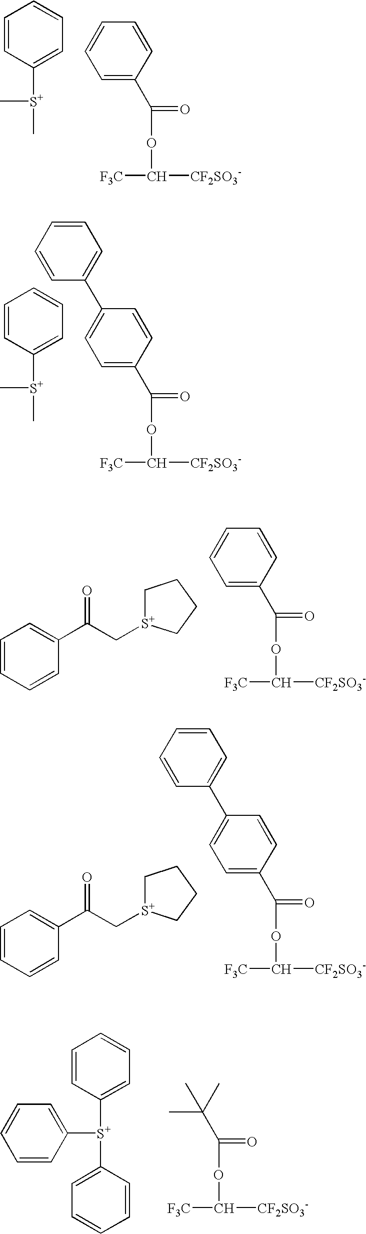

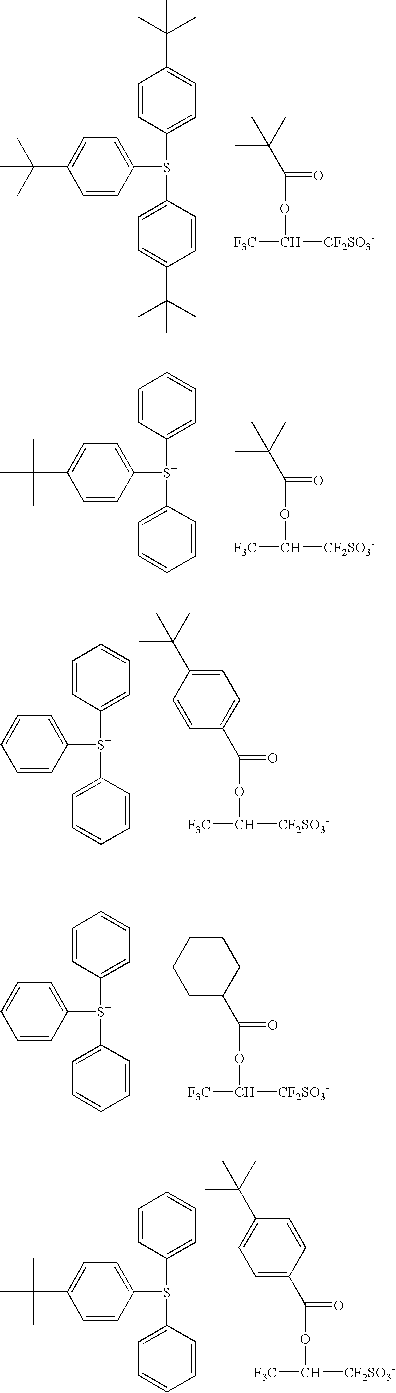

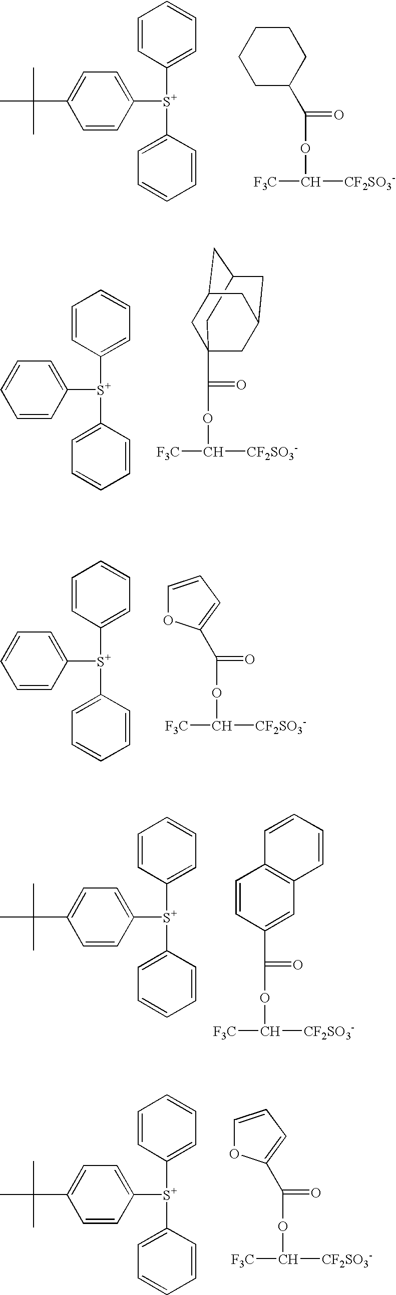

The salt represented by the formula (XI):

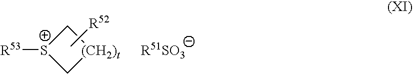

wherein R⁵¹ represents an alkyl group, a cycloalkyl group or a fluorinated alkyl group, R⁵² represents a hydrogen atom, a hydroxyl group, a halogen atom, an alkyl group, a halogenated alkyl group or an alkoxyl group, R⁵³ represents an optionally substituted aryl group and t represents an integer of 1 to 3, can be used as the acid generator.

In R⁵¹, the alkyl group preferably has 1 to 10 carbon atoms, more preferably 1 to 8 carbon atoms and especially preferably 1 to 4 carbon atoms. The cycloalkyl group preferably has 4 to 15 carbon atoms, more preferably 4 to 12 carbon atoms, much more preferably 4 to 10, and especially preferably 6 to 10 carbon atoms. The fluorinated alkyl group preferably has 1 to 10 carbon atoms, more preferably 1 to 8 carbon atoms and especially preferably 1 to 4 carbon atoms. The ratio of number of fluorine atom to total number of fluorine atoms and hydrogen atoms in the fluorinated alkyl group is preferably 10% or more, and more preferably 50% or more, and perfluoroalkyl group is especially preferable.

R⁵¹ is preferably a linear alkyl group or a fluorinated linear alkyl group.

Examples of the halogen atom include a fluorine atom, a chlorine atom, a bromine atom and an iodine atom, and a fluorine atom is preferable.

In R⁵², the alkyl group preferably has 1 to 5 carbon atoms, more preferably 1 to 4 carbon atoms and especially preferably 1 to 3 carbon atoms. Examples of the halogenated alkyl group include an alkyl group having one or more halogen atoms and examples of the halogen atom include the same as described above. The ratio of number of halogen atom to total number of halogen atoms and hydrogen atoms in the halogenated alkyl group is preferably 50% or more, and perhaloalkyl group is especially preferable. The alkoxy group preferably has 1 to 5 carbon atoms, more preferably 1 to 4 carbon atoms and especially preferably 1 to 3 carbon atoms. R⁵² is preferably a hydrogen atom.

R⁵³ is preferably an optionally substituted phenyl group or an optionally substituted naphthyl group, and more preferably an optionally substituted phenyl group and especially preferably a phenyl group. Examples of the optionally substituted aryl group include an unsubstituted aryl group such as a phenyl group and a naphthyl group, an aryl group having a hydroxyl group, an aryl group having a lower alkyl group, and an aryl group having a lower alkoxy group. The lower alkyl group preferably has 1 to 6 carbon atoms, more preferably 1 to 4 carbon atoms and especially preferably 1 carbon atom.

In the formula (XI), t is preferably 2 or 3 and more preferably 3.

Examples of the salt represented by the formula (XI) include the followings.

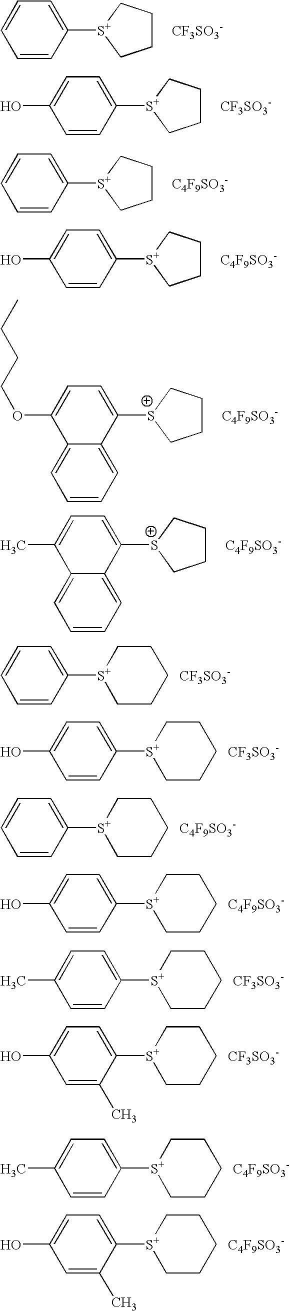

As the acid generator, a salt represented by the formula (XII) or (XIII):

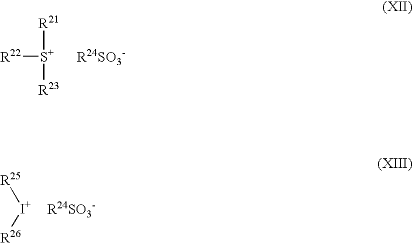

wherein R²¹ represents an aryl group, R²² and R²³ independently each represent an aryl group, an alkyl group or a cycloalkyl group, R²⁴ represents an alkyl group, a cycloalkyl group or a fluorinated alkyl group, R²⁵ represents an aryl group and R²⁶ represents an aryl group, an alkyl group or a cycloalkyl group, can also be used.

Examples of the alkyl group of R²², R²³ and R²⁶ include a C1-C10 alkyl group such as a methyl group, an ethyl group, a propyl group, an isopropyl group, a butyl group, a isobutyl group, a pentyl group, a hexyl group, a nonyl group and a decyl group, and a C1-C5 alkyl group is preferable, and a methyl group is more preferable. Examples of the cycloalkyl group of R²², R²³ and R²⁶ include a C3-C10 alkyl group such as a cyclopentyl group and a cyclohexyl group. Examples of the aryl group of R²¹, R²², R²³, R²⁵ and R²⁶ include a C6-C20 aryl group, and a phenyl group and a naphthyl group are preferable. The aryl group can have one or more substituents and examples of the substituent include an alkyl group, an alkoxy group and a halogen atom. Examples of the alkyl group include a C1-C5 alkyl group, and a methyl group, an ethyl group, a propyl group, a butyl group or a tert-butyl group is preferable. Examples of the alkoxy group include a C1-C5 alkoxy group, and a methoxy group or an ethoxy group is preferable. Examples of the halogen atom include a fluorine atom.

In the formula (XII), R²² is preferably aryl group, and R²² and R²³ are more preferably aryl groups. It is preferred that R²¹, R²² and R²³ independently each represent a phenyl group or a naphthyl group.

Examples of R²⁴ include the same as described in R⁷.

In the formula (XIII), R²⁶ is preferably aryl group, and R²⁵ and R²⁶ are more preferably phenyl groups.

Examples of the salts represented by the formulae (XII) and (XIII) include diphenyliodonium trifluoromethanesulfonate, diphenyliodonium nonafluorobutanesulfonate, bis(4-tert-butylphenyl)iodonium trifluoromethanesulfonate, bis(4-tert-butylphenyl)iodonium nonafluorobutanesulfonate, triphenylsulfonium trifluoromethanesulfonate, triphenylsulfonium heptafluoropropanesulfonate, triphenylsulfonium nonafluorobutanesulfonate, tris(4-methylphenyl)sulfonium trifluoromethanesulfonate, heptafluoropropanesulfonate, tris(4-methylphenyl)sulfonium nonafluorobutanesulfonate, dimethyl(4-hydroxynaphthyl)sulfonium trifluoromethanesulfonate, dimethyl(4-hydroxynaphthyl)sulfoniumheptafluoropropanesulfonate, dimethyl(4-hydroxynaphthyl)sulfonium nonafluorobutanesulfonate, dimethylphenylsulfonium trifluoromethanesulfonate, dimethylphenylsulfonium heptafluoropropanesulfonate, dimethylphenylsulfonium nonafluorobutanesulfonate, trifluoromethanesulfonate, diphenylmethylsulfonium heptafluoropropanesulfonate, diphenylmethylsulfonium nonafluorobutanesulfonate, (4-methylphenyl)diphenylsulfonium trifluoromethanesulfonate, (4-methylphenyl)diphenylsulfonium heptafluoropropanesulfonate, (4-methylphenyl)diphenylsulfonium nonafluorobutanesulfonate, (4-methoxyphenyl)diphenylsulfonium trifluoromethanesulfonate, (4-methoxyphenyl)diphenylsulfonium heptafluoropropanesulfonate, (4-methoxyphenyl)diphenylsulfonium nonafluorobutanesulfonate, tris(4-tert-butylphenyl)sulfonium trifluoromethanesulfonate, tris(4-tert-butylphenyl)sulfonium heptafluoropropanesulfonate, tris(4-tert-butylphenyl)sulfonium nonafluorobutanesulfonate, diphenyl(1-(4-methoxy)naphthyl)sulfonium trifluoromethanesulfonate, diphenyl(1-(4-methoxy)naphthyl)sulfonium heptafluoropropanesulfonate, diphenyl(1-(4-methoxy)naphthyl)sulfonium nonafluorobutanesulfonate, di(1-naphthyl)phenylsulfonium trifluoromethanesulfonate, di(1-naphthyl)phenylsulfonium heptafluoropropanesulfonate, di(1-naphthyl)phenylsulfonium nonafluorobutanesulfonate, 1-(4-butoxynaphthyl)tetrahydrothiophenium perfluorooctanesulfonate, 1-(4-butoxynaphthyl)tetrahydrothiophenium 2-bicyclo[2.2.1.]hept-2-yl-1,1,2,2-tetrafluoroethanesulfonate, and N-nonafluorobutanesulfonyloxybicyclo[2.2.1]hept-S-ene-2,3-dicar boxylimide.

A salt wherein a cation part is the cation of the salt represented by the formula (XII) or (XIII) and an anion part is the anion of the salt represented by the formula (X-1), (X-2) or (X-3) can be also used as the acid generator.

As the acid generator, the followings can be used as the acid generator.

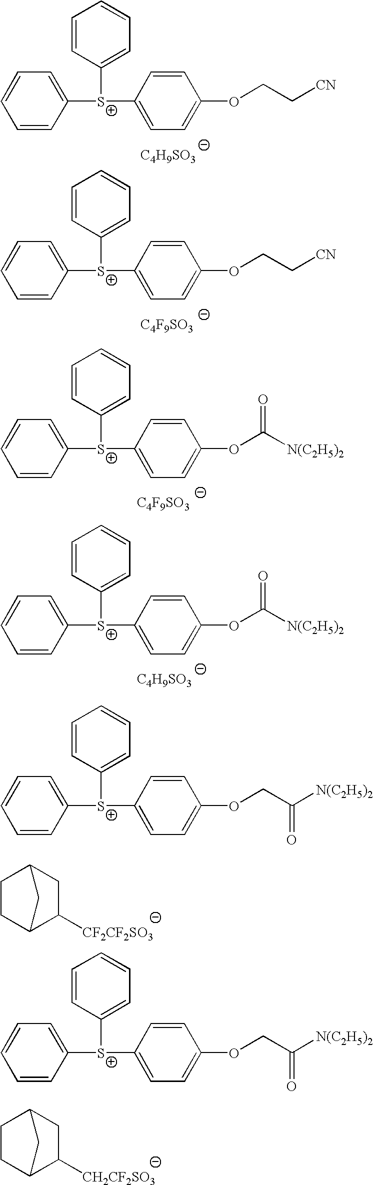

Examples of the oximesulfonate compound include a compound having a group represented by the formula (XVI):

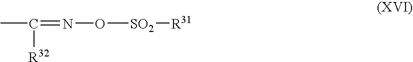

wherein R³¹ and R³² independently each represent an organic group.

R³¹ is preferably an alkyl group, a halogenated alkyl group or an aryl group. The alkyl group preferably has 1 to 20 carbon atoms, more preferably 1 to 8 carbon atoms, much more preferably 1 to 6 carbon atoms and especially preferably 1 to 4 carbon atoms. Examples of the halogenated alkyl group include a fluorinated alkyl group, a chlorinated alkyl group, a brominated alkyl group and an iodinated alkyl group, and a fluorinated alkyl group is preferable. Examples of the aryl group include a C4-C20 aryl group, and a C4-C10 aryl group is preferable, and a C6-C10 aryl group is more preferable. The aryl group can have one more halogen atoms such as a fluorine atom, a chlorine atom, a bromine atom and an iodine atom. R³¹ is more preferably a C1-C4 alkyl group or a C1-C4 fluorinated alkyl group.

R³² is preferably an alkyl group, a halogenated alkyl group, an aryl group or a cyano group, and examples of the alkyl group and aryl group include the same as described in R³¹. R³² is more preferably a cyano group, a C1-C8 alkyl group, or a C1-C8 a halogenated alkyl group.

Preferable examples of the oximesulfonate compound include compounds represented by the formulae (XVII) and (XVIII):

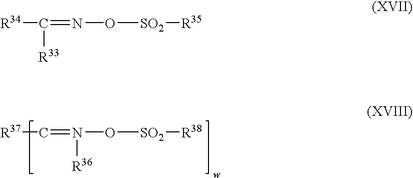

wherein R³³ represents a cyano group, an alkyl group or a halogenated alkyl group, R³⁴ represents an aryl group, R³⁵ represents an alkyl group or a halogenated alkyl group, R³⁶ represents a cyano group, an alkyl group or a halogenated alkyl group, R³⁷ represents a w valent aromatic hydrocarbon group, R³⁸ represents an alkyl group or a halogenated alkyl group, and w represent 2 or 3.

In R³³, the alkyl group and the halogenated alkyl group preferably has 1 to 10 carbon atoms, more preferably 1 to 8 carbon atoms, and especially preferably 1 to 6 carbon atoms. R³³ is preferably a halogenated alkyl group and more preferably a fluorinated alkyl group. The fluorinated alkyl group in which the ratio of number of fluorine atom to total number of fluorine atoms and hydrogen atoms is 70% or more is preferable, and the fluorinated alkyl group in which the ratio of number of fluorine atom to total number of fluorine atoms and hydrogen atoms is 90% or more is more preferable, and perfluoroalkyl group is especially preferable.

In R³⁴, examples of the aryl group include a phenyl group, a biphenyl group, a fluorenyl group, a naphthyl group, an anthryl group and a phenanthryl group, and a heteroaryl group having a heteroatom such as a nitrogen atom, a sulfur atom and an oxygen atom. The aryl group can have one or more substituents, and examples of the substituents include a C1-C10 alkyl group, a C1-C10 halogenated alkyl group, a C1-C10 alkoxy group. The alkyl group and the halogenated alkyl group preferably have 1 to 8 carbon atoms and more preferably 1 to 4 carbon atoms. The halogenated alkyl group is preferably a fluorinated alkyl group.

In R³⁵, examples of the alkyl group and the halogenated alkyl group include the same as described in R³³.

In R³⁶, examples of the alkyl group and the halogenated alkyl group include the same as described in R³³. Examples of the w valent aromatic hydrocarbon group include a benzenediyl group. In R³⁸, examples of the alkyl group and the halogenated alkyl group include the same as described in R³⁵, and w is preferably 2.

Specific examples of the oximesulfonate compound include compounds described in JP 2007-286161 A, JP 9-208554 A and WO 2004/074242 A2. Preferable examples thereof include the followings.

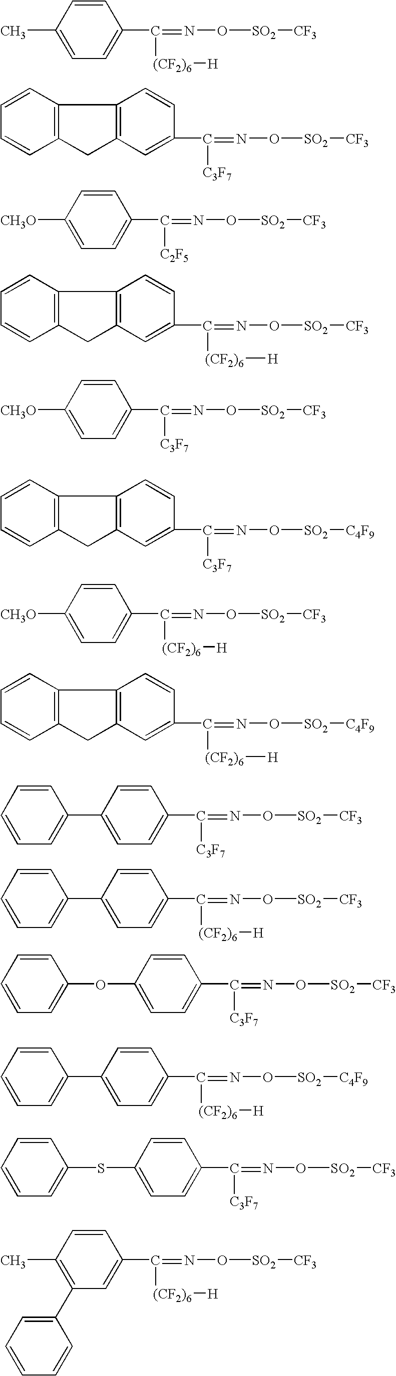

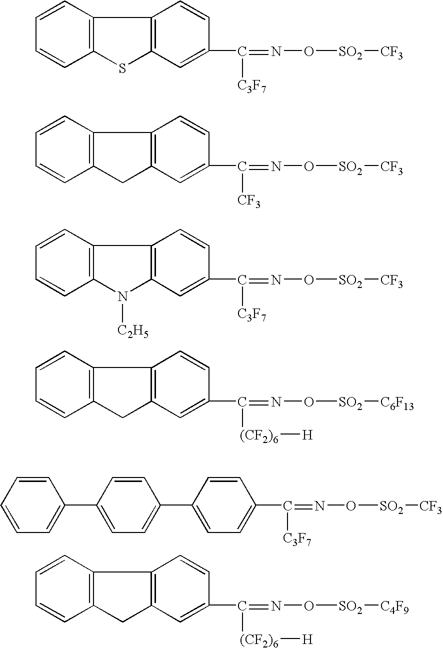

As the acid generator, a diazomethane compound such as a bis(alkylsulfonyl)diazomethane, a bis(arylsulfonyl)diazomethane and a poly-bis(sulfonyl)diazomethane, a nitrobenzylsulfonate compound, an iminosulfonate compound and a dislufone compound can also be used.

Examples of the bis(alkylsulfonyl)diazomethane and the bis(arylsulfonyl)diazomethane include bis(isopropylsulfonyl)diazomethane, bis(p-toluenesulfonyl)diazomethane, bis(1,1-dimethylethylsulfonyl)diazomethane, bis(cyclohexylsulfonyl)diazomethane and bis(2,4-dimethylphenylsulfonyl)diazomethane. Additionally, diazomethane compounds described in JP 11-035551 A, JP 11-035552 A and JP 11-035553 A can also be used.

Examples of the poly-bis(sulfonyl)diazomethane include 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane and 1,10-bis(cyclohexylsulfonyldiazomethylsulfonyl)decane.

Onium salts having a fluorinated alkylsuofonate anion is preferable.

Component (b) contains one or more kinds of the acid generator.

The first photoresist composition usually contains 70 to 99.9% by weight of Component (a), preferably 80 to 99.9% by weight of Component (a) and more preferably 90 to 99% by weight of Component (a) based on the amount of solid components. The first photoresist composition usually contains 0.1 to 30% by weight of Component (b), preferably contains 0.1 to 20% by weight of Component (b) and more preferably 1 to 10% by weight of Component (b). In this specification, “solid components” means sum of components other than a solvent(s) in the photoresist composition.

Next, Component (c) will be illustrated.

In the formula (X), R¹¹, R¹², R¹³ and R¹⁴ each independently represent a C1-C6 alkyl group substituted with a C1-C6 alkoxy group, and R¹⁵ and R¹⁶ each independently represent a C1-C6 alkyl group or a C6-C10 aromatic hydrocarbon group which may have one or more substituents.

Examples of the C1-C6 alkyl group substituted with a C1-C6 alkoxy group include —CH₂OCH₃, —CH₂OC₂H₅, —CH₂OC₃H₇, —CH₂OCH(CH₃)₂, —(CH₂)₂CH₃, —(CH₂)₂OC₂H₅, —(CH₂)₂OC₃H₇, —(CH₂)₃OCH₃—(CH₂)₃OC₂H₅, —(CH₂)₃OC₃H₇ and —(CH₂)₆OCH₃. Examples of the C1-C6 alkyl group include a methyl group, an ethyl group, a propyl group, an isopropyl group, a butyl group, an isobutyl group, a sec-butyl group, a tert-butyl group, a pentyl group and a hexyl group, and a C1-C4 alkyl group is preferable and a C1 or C2 alkyl group is more preferable and a methyl group is especially preferable. Examples of the C6-C10 aromatic hydrocarbon group include a phenyl group and a naphthyl group, and examples of the substituent include a halogen atom and a C1-C6 alkyl group.

Specific examples of the cross-linking agent (X) include the compound represented by No. 1 to No. 10 in Table 1 and the compound represented by No. 2 or No. 3 is preferable. In Table 1, R-1 means —CH₂OCH₃, R-2 means —CH₂OCH(CH₃)₂, R-3 means —CH₃, R-4 means —C₃H₇, and R-5 means —C₆H₅.

TABLE 1

| No. | R¹¹ | R¹² | R¹³ | R¹⁴ | R¹⁵ | R¹⁶ |
|---|---|---|---|---|---|---|
| 1 | R-1 | R-1 | R-1 | R-1 | R-3 | R-3 |
| 2 | R-1 | R-1 | R-1 | R-1 | R-3 | R-4 |
| 3 | R-1 | R-1 | R-1 | R-1 | R-3 | R-5 |
| 4 | R-1 | R-1 | R-1 | R-1 | R-4 | R-5 |
| 5 | R-1 | R-1 | R-1 | R-1 | R-5 | R-5 |
| 6 | R-2 | R-2 | R-2 | R-2 | R-3 | R-3 |
| 7 | R-2 | R-2 | R-2 | R-2 | R-3 | R-4 |
| 8 | R-2 | R-2 | R-2 | R-2 | R-3 | R-5 |
| 9 | R-2 | R-2 | R-2 | R-2 | R-4 | R-5 |
| 10 | R-2 | R-2 | R-2 | R-2 | R-5 | R-5 |

As the cross-linking agent (X), commercially available one is usually used.

In the first photoresist composition, the amount of Component (c) is usually 0.5 to 30 parts by weight per 100 parts by weight of Component (a), preferably 0.5 to 10 parts by weight, more preferably 1 to 5 parts by weight, and especially preferably 1.5 to 2.5 parts by weight.

The first photoresist composition can contain the other cross-linking agent than the cross-linking agent (X). Examples of the other cross-linking agent include a compound having a hydroxymethylamino group, which can be obtained by reacting a compound having an amino group with formaldehyde or with formaldehyde and a lower alcohol, and an aliphatic hydrocarbon compound having two or more ethylene oxide structures. Examples of the compound having an amino group include acetoguanamine, benzoguanamine, urea, alkyleneurea such as ethyleneurea and propyleneurea, and glycoluril. A compound which can be obtained by reacting urea with formaldehyde or with formaldehyde and a lower alcohol, a compound which can be obtained by reacting alkyleneurea with formaldehyde or with formaldehyde and a lower alcohol and a compound which can be obtained by reacting glycoluril with formaldehyde or with formaldehyde and a lower alcohol are preferable, and a compound which can be obtained by reacting glycoluril with formaldehyde or with formaldehyde and a lower alcohol is more preferable.

Examples of the compound which can be obtained by reacting urea with formaldehyde or with formaldehyde and a lower alcohol include bis(methoxymethyl)urea, bis(ethoxymethyl)urea, bis(propoxymethyl)urea and bis(butoxymethyl)urea, and bis(methoxymethyl)urea is preferable.

Examples of the compound which can be obtained by reacting alkyleneurea with formaldehyde or with formaldehyde and a lower alcohol include a compound represented by the formula (XIX):

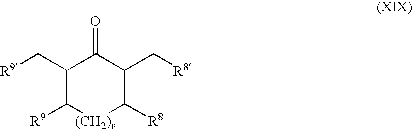

wherein R⁸ and R⁹ independently each represents a hydroxyl group or a lower alkoxy group, R⁸′ and R⁹′ independently each represents a hydrogen atom, a hydroxyl group or a lower alkoxy group, and v represents 0, 1 or 2.

The lower alkoxy group is preferably a C1-C4 alkoxy group.

R⁸ and R⁹ are preferably the same and R⁸′ and R⁹′ are preferably the same, and v is preferably 0 or 1.

Examples of the compound represented by the formula (XIX) include monohydroxymethylated ethyleneurea, dihydroxymethylated ethyleneurea, monomethoxymethylated ethyleneurea, dimethoxymethylated ethyleneurea, ethoxymethylated ethyleneurea, diethoxymethylated ethyleneurea, propoxymethylated ethyleneurea, dipropoxymethylated ethyleneurea, butoxymethylated ethyleneurea, dibutoxymethylated ethyleneurea, monohydroxymethylated propyleneurea, dihydroxymethylated propyleneurea, monomethoxymethylated propyleneurea, dimethoxymethylated propyleneurea, ethoxymethylated propyleneurea, diethoxymethylated propyleneurea, propoxymethylated propyleneurea, dipropoxymethylated propyleneurea, butoxymethylated propyleneurea, dibutoxymethylated propyleneurea, 1,3-(dimethoxymethyl)-4,5-dihydroxy-2-imidazolidinone and 1,3-(dimethoxymethyl)-4,5-dimethoxy-2-imidazolidinone.

Examples of the compound which can be obtained by reacting glycoluril with formaldehyde or with formaldehyde and a lower alcohol include mono(tetrahydroxymethylated) glycoluril, di(tetrahydroxymethylated) glycoluril, tri(tetrahydroxymethylated) glycoluril, tetra(tetrahydroxymethylated) glycoluril, mono(tetramethoxymethylated) glycoluril, di(tetramethoxymethylated) glycoluril, tri(tetramethoxymethylated) glycoluril, tetra(tetramethoxymethylated) glycoluril, mono(tetraethoxymethylated) glycoluril, di(tetraethoxymethylated) glycoluril, tri(tetraethoxymethylated) glycoluril, tetra(tetraethoxymethylated) glycoluril, mono(tetrapropoxymethylated) glycoluril, di(tetrapropoxymethylated) glycoluril, tri(tetrapropoxymethylated) glycoluril, tetra(tetrapropoxymethylated) glycoluril, mono(tetrabutoxymethylated) glycoluril, di(tetrabutoxymethylated) glycoluril, tri(tetrabutoxymethylated) glycoluril and tetra(tetrabutoxymethylated) glycoluril.

In the first photoresist composition, the total amount of the cross-linking agent (X) and the other cross-linking agent is usually 0.5 to 30 parts by weight per 100 parts by weight of Component (a), preferably 0.5 to 10 parts by weight, more preferably 1 to 5 parts by weight, and especially preferably 1.5 to 2.5 parts by weight.

In the first photoresist composition, performance deterioration caused by inactivation of acid which occurs due to post exposure delay can be diminished by adding an organic base compound, particularly a nitrogen-containing organic base compound as a quencher.

Specific examples of the nitrogen-containing organic base compound include nitrogen-containing organic base compounds represented by the following formulae:

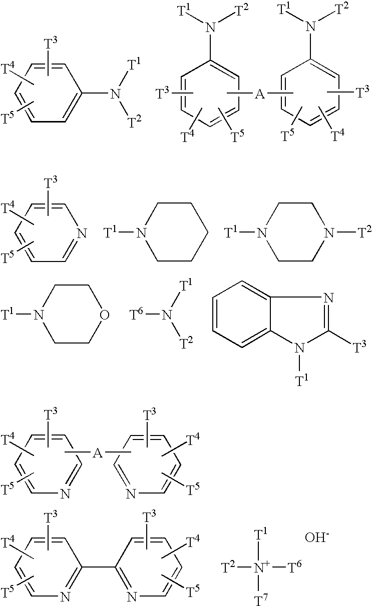

wherein T¹, T² and T⁷ each independently represent a hydrogen atom, a C1-C6 aliphatic hydrocarbon group, a C5-C10 alicyclic hydrocarbon group or a C6-C20 aromatic hydrocarbon group, and the aliphatic hydrocarbon group, the alicyclic hydrocarbon group and the aromatic hydrocarbon group may have one or more groups selected from the group consisting of a hydroxyl group, an amino group which may be substituted with a C1-C4 aliphatic hydrocarbon group and a C1-C6 alkoxy group, T³, T⁴ and T⁵ each independently represent a hydrogen atom, a C1-C6 aliphatic hydrocarbon group, a C5-C10 alicyclic hydrocarbon group, a C6-C20 aromatic hydrocarbon group or a C1-C6 alkoxy group, and the aliphatic hydrocarbon group, the alicyclic hydrocarbon group, the aromatic hydrocarbon group and the alkoxy group may have one or more groups selected from the group consisting of a hydroxyl group, an amino group which may be substituted with a C1-C4 aliphatic hydrocarbon group and a C1-C6 alkoxy group, T⁶ represents a C1-C6 aliphatic hydrocarbon group or a C5-C10 alicyclic hydrocarbon group, and the aliphatic hydrocarbon group and the alicyclic hydrocarbon group may have one or more groups selected from the group consisting of a hydroxyl group, an amino group which may be substituted with a C1-C4 aliphatic hydrocarbon group and a C1-C6 alkoxy group, and
A represents —CO—, —NH—, —S—, —S—S— or a C2-C6 alkylene group,

Examples of the amino group which may be substituted with the C1-C4 aliphatic hydrocarbon group include an amino group, a methylamino group, an ethylamino group, a butylamino group, a dimethylamino group and a diethylamino group. Examples of the C1-C6 alkoxy group include a methoxy group, an ethoxy group, a propoxy group, an isopropoxy group, a butoxy group, a tert-butoxy group, a pentyloxy group, a hexyloxy group and a 2-methoxyethoxy group.

Specific examples of the aliphatic hydrocarbon group which may have one or more groups selected from the group consisting of a hydroxyl group, an amino group which may be substituted with a C1-C4 aliphatic hydrocarbon group, and a C1-C6 alkoxy group include a methyl group, an ethyl group, a propyl group, an isopropyl group, a butyl group, a tert-butyl group, a pentyl group, a hexyl group, an octyl group, a nonyl group, a decyl group, a 2-(2-methoxyethoxy)ethyl group, a 2-hydroxyethyl group, a 2-hydroxypropyl group, a 2-aminoethyl group, a 4-aminobutyl group and a 6-aminohexyl group.

Specific examples of the alicyclic hydrocarbon group which may have one or more groups selected from the group consisting of a hydroxyl group, an amino group which may be substituted with a C1-C4 aliphatic hydrocarbon group and a C1-C6 alkoxy group include a cyclopentyl group, a cyclohexyl group, a cycloheptyl group and a cyclooctyl group.

Specific examples of the aromatic hydrocarbon group which may have one or more groups selected from the group consisting of a hydroxyl group, an amino group which may be substituted with a C1-C4 aliphatic hydrocarbon group and a C1-C6 alkoxy group include a phenyl group and naphthyl group.

Specific examples of the alkoxy group include a methoxy group, an ethoxy group, a propoxy group, an isopropoxy group, a butoxy group, a tert-butoxy group, a pentyloxy group and a hexyloxy group.

Specific examples of the alkylene group include an ethylene group, a trimethylene group, a tetramethylene group, a methylenedioxy group and an ethylene-1,2-dioxy group.

Specific examples of the nitrogen-containing organic base compounds include hexylamine, heptylamine, octylamine, nonylamine, decylamine, aniline, 2-methylaniline, 3-methylaniline, 4-methylaniline, 4-nitroaniline, 1-naphthylamine, 2-naphthylamine, ethylenediamine, tetramethylenediamine, hexamethylenediamine, 4,4′-diamino-1,2-diphenylethane, 4,4′-diamino-3,3′-dimethyldiphenylmethane, 4,4′-diamino-3,3′-diethyldiphenylmethane, dibutylamine, dipentylamine, dihexylamine, diheptylamine, dioctylamine, dinonylamine, didecylamine, N-methylaniline, piperidine, diphenylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethyldipentylamine, ethyldihexylamine, ethyldiheptylamine, ethyldioctylamine, ethyldinonylamine, ethyldidecylamine, dicyclohexylmethylamine, tris[2-(2-methoxyethoxy)ethyl]amine, triisopropanolamine, N,N-dimethylaniline, 2,6-diisopropylaniline, imidazole, benzimidazole, pyridine, 4-methylpyridine, 4-methylimidazole, bipyridine, 2,2′-dipyridylamine, di-2-pyridyl ketone, 1,2-di(2-pyridyl)ethane, 1,2-di(4-pyridyl)ethane, 1,3-di(4-pyridyl)propane, 1,2-bis(2-pyridyl)ethylene, 1,2-bis(4-pyridyl)ethylene, 1,2-bis(4-pyridyloxy)ethane, 4,4′-dipyridyl sulfide, 4,4′-dipyridyl disulfide, 2,2′-dipicolylamine, 3,3′-dipicolylamine, tetramethylammonium hydroxide, tetrabutylammonium hydroxide, tetrahexylammonium hydroxide, tetraoctylammonium hydroxide, phenyltrimethylammonium hydroxide, (3-trifluoromethylphenyl)trimethylammonium hydroxide and (2-hydroxyethyl) trimethylammonium hydroxide (so-called “choline”).

A hindered amine compound having a piperidine skeleton as disclosed in JP 11-52575 A1 can be also used as the quencher.

In the point of forming patterns having higher resolution, the quaternary ammonium hydroxide is preferably used as the quencher.

When the basic compound is used as the quencher, the first photoresist composition preferably includes 0.01 to 1% by weight of the basic compound based on the total amount of the solid components.

The first photoresist composition can contain, if necessary, a small amount of various additives such as a sensitizer, a dissolution inhibitor, other polymers, a surfactant, a stabilizer and a dye as long as the effect of the present invention is not prevented.

The first photoresist composition is usually in the form of a photoresist liquid composition in which the above-mentioned ingredients are dissolved in a solvent. Solvents generally used in the art can be used. The solvent used is sufficient to dissolve the above-mentioned ingredients, have an adequate drying rate, and give a uniform and smooth coat after evaporation of the solvent.

Examples of the solvent include a glycol ether ester such as ethyl cellosolve acetate, methyl cellosolve acetate and propylene glycol monomethyl ether acetate; an acyclic ester such as ethyl lactate, butyl acetate, amyl acetate and ethyl pyruvate; a ketone such as acetone, methyl isobutyl ketone, 2-heptanone and cyclohexanone; and a cyclic ester such as γ-butyrolactone. These solvents may be used alone and two or more thereof may be mixed to use.

The second photoresist composition usually contains the above-mentioned one or more resins, the above-mentioned acid generators and one or more solvents. The second photoresist composition can contain the above-mentioned one or more quencher and the above-mentioned additives. The second photoresist composition can contain the above-mentioned cross-linking agent. The second photoresist composition may be the same as the first photoresist composition, and may be different from the first photoresist composition.

The process for producing a photoresist pattern of the present invention comprises the following steps (1) to (11):

(1) a step of applying the first photoresist composition on a substrate followed by conducting drying, thereby forming the first photoresist film,

(2) a step of prebaking the first photoresist film,

(3) a step of exposing the prebaked first photoresist film to radiation,

(4) a step of baking the exposed first photoresist film,

(5) a step of developing the baked first photoresist film with the first alkaline developer, thereby forming the first photoresist pattern,

(6) a step of making the formed first photoresist pattern inactive to radiation in the following step (9), making the formed first photoresist pattern insoluble in an alkaline developer or making the formed first photoresist pattern insoluble in the second photoresist composition used in the following step (7),

(7) a step of applying the second photoresist composition on the substrate on which the first photoresist pattern has been formed, followed by conducting drying, thereby forming the second photoresist film,

(8) a step of prebaking the second photoresist film,

(9) a step of exposing the prebaked second photoresist film to radiation,

(10) a step of baking the exposed second photoresist film, and

(11) a step of developing the baked second photoresist film with the second alkaline developer, thereby forming the second photoresist pattern.

In the step (1), the first photoresist composition is applied onto a substrate by a conventional process such as spin coating. Examples of the substrate include a semiconductor substrate such as a silicon wafer, a plastic substrate, a metallic substrate, a ceramic substrate and these substrates on which a insulating film or a conducting film is applied. An anti-reflective coating film can be formed on the substrate. Examples of the anti-reflective coating composition for forming the anti-reflective coating film include commercially available anti-reflective coating compositions such as “ARC-29A-8” available from Brewer Co. The anti-reflective coating film is usually formed by applying onto the substrate by a conventional process such as spin coating followed by baking. The baking temperature is usually 190 to 250° C., preferably 195 to 235° C. and more preferably 200 to 220° C. The baking time is usually 5 to 60 seconds.

In the step (1), while the film thickness of the first photoresist composition is not limited, it is preferably tens of nanometers to hundreds of micrometers. After applying the first photoresist composition on the substrate, the formed first photoresist composition film is dried, thereby forming the first photoresist film. Examples of a drying process include natural drying, draught drying and drying under reduced pressure. The drying temperature is usually 10 to 120° C., and preferably 25 to 80° C., and the drying time is usually 10 to 3,600 seconds and preferably 30 to 1,800 seconds.

In the step (2), the first photoresist film formed in the step (1) is prebaked. The prebaking is usually conducted using a heating device. The prebaking temperature is usually 80 to 140° C., and the prebaking time is usually 10 to 600 seconds.

In the step (3), the first photoresist film prebaked in the step (2) is exposed to radiation. The exposure is usually conducted using a conventional exposure system such as KrF excimer laser exposure system (wave length: 248 nm), ArF excimer laser dry exposure system (wave length: 193 nm), ArF excimer laser liquid immersion exposure system (wave length: 193 nm), F₂ laser exposure system (wavelength: 157 nm) and a system radiating a harmonic laser belonging to far-ultraviolet region or vacuum ultraviolet region by converting a laser from a solid-state laser source by wavelength conversion.

In the step (4), the first photoresist film exposed in the step (3) is baked. The baking is usually conducted using a heating device. The baking temperature is usually 70 to 140° C., and the baking time is usually 30 to 600 seconds.

In the step (5), the first photoresist film baked in the step (4) is developed with the first alkaline developer, thereby forming the first photoresist pattern. As the first alkaline developer, any one of various alkaline aqueous solution used in the art is used. Generally, an aqueous solution of tetramethylammonium hydroxide or (2-hydroxyethyl)trimethylammonium hydroxide (commonly known as “choline”) is used.

In the step (6), the first photoresist pattern formed in the step (5) is made inactive to radiation in the following step (9), made the formed first photoresist pattern insoluble in an alkaline developer or made the formed first photoresist pattern insoluble in the second photoresist composition used in the following step (7). Usually, the formed first photoresist pattern is baked using a heating device. The heating device may be the same as that used in the step (2) and may be different from that used in the step (2). A hotplate or an oven is usually used as the heating device, and a hotplate is preferable. The baking temperature is usually 190 to 250° C., preferably 195 to 235° C., and more preferably 200 to 220° C. The baking time is usually 10 to 60 seconds. The baking can be conducted in several batches.

In the step (7), the second photoresist composition is applied on the substrate on which the first photoresist pattern has been formed in the step (6), followed by conducting drying, thereby forming the second photoresist film. This step is usually conducted according to the same manner as described in the step (1).

In the step (8), the second photoresist film formed in the step (7) is prebaked, and this step is usually conducted according to the same manner as described in the step (2).

In the step (9), the prebaked second photoresist film is exposed to radiation, and this step is usually conducted according to the same manner as described in the step (3).

In the step (10), the exposed second photoresist film is baked, and this step is usually conducted according to the same manner as described in the step (4).

In the step (11), the baked second photoresist film is developed with the second alkaline developer, thereby forming the second photoresist pattern. As the second alkaline developer, the same as described as the first alkaline developer is usually used. This step is usually conducted according to the same manner as described in the step (5).

It should be construed that embodiments disclosed here are examples in all aspects and not restrictive. It is intended that the scope of the present invention is determined not by the above descriptions but by appended Claims, and includes all variations of the equivalent meanings and ranges to the Claims.

The present invention will be described more specifically by Examples, which are not construed to limit the scope of the present invention. The “%” and “part(s)” used to represent the content of any compound and the amount of any material to be used in the following Examples are on a weight basis unless otherwise specifically noted. The weight-average molecular weight (Mw) and the number-average molecular weight (Mn) of resins used in the following examples is a value found by gel permeation chromatography and the analysis condition is as followed. The glass-transition temperature (Tg) of the obtained resin was measured using a differential scanning calorimeter (Q2000 Type, manufactured by TA Instruments Co.).

<Gel permeation chromatography analysis condition>
Apparatus: HLC-8120GPC Type, manufactured by TOSOH CORPORATION
Column: Three Columns of TSKgel Multipore HXL-M with a guard column, manufactured by TOSOH CORPORATION
Eluting Solvent: tetrahydrofuran
Flow rate: 1.0 mL/minute
Detector: RI detector
Column Temperature: 40° C.
Injection amount: 100 μL
Standard reference material: standard polystyrene

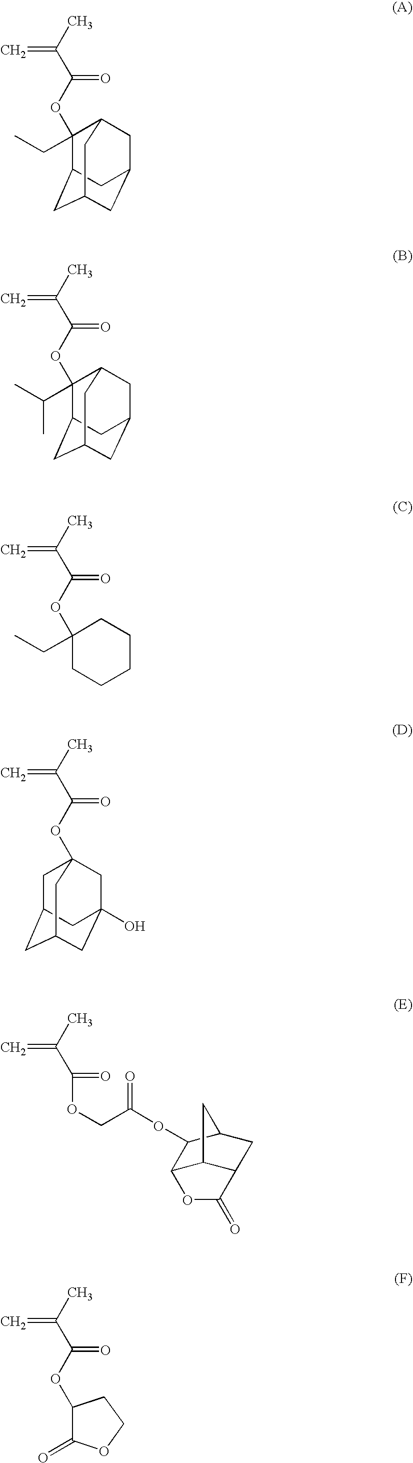

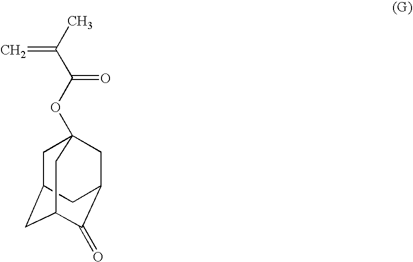

### Resin Synthesis Example 1

Into a four-necked flask equipped with a condenser and a thermometer, 27.78 parts of 1,4-dioxane was added, and then a nitrogen gas was blown into it for 30 minutes to substitute a gas in the flask to a nitrogen gas. After heating it up to 73° C. under nitrogen, a solution obtained by mixing 15.00 parts of monomer (B), 5.61 parts of monomer (C), 2.89 parts of monomer (D), 12.02 parts of monomer (E), 10.77 parts of monomer (F), 0.34 part of 2,2′-azobisisobutyronitrile, 1.52 part of 2,2′-azobis(2,4-dimethylvaleronitrile) and 63.85 parts of 1,4-dioxane was added dropwise thereto over 2 hours at 73° C. The resultant mixture was heated at 73° C. for 5 hours. The reaction mixture was cooled down to room temperature and diluted with 50.92 parts of 1,4-dioxane. The resultant mixture was pored into a mixed solution of 481 parts of methanol and 120 parts of ion-exchanged water with stirring to cause precipitation. The precipitate was isolated and washed three times with 301 parts of methanol followed by drying under reduced pressure to obtain 37 parts of a resin having a Mw of 7.90×10³, degree of dispersion (Mw/Mn) of 1.96 and Tg of 146° C. The yield thereof was 80%. This resin had the following structural units. This is called as resin A1.

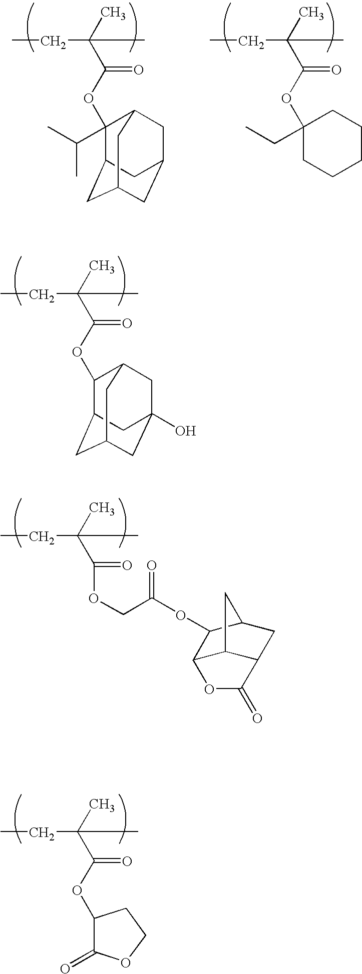

### Resin Synthesis Example 2

Into a four-necked flask equipped with a condenser and a thermometer, 50.40 parts of 1,4-dioxane was added, and then a nitrogen gas was blown into it for 30 minutes to substitute a gas in the flask to a nitrogen gas. After heating it up to 66° C. under nitrogen, a solution obtained by mixing 24.00 parts of monomer (A), 5.53 parts of monomer (C), 25.69 parts of monomer (D), 28.78 parts of monomer (F), 0.56 part of 2,2′-azobisisobutyronitrile, 2.55 part of 2,2′-azobis(2,4-dimethylvaleronitrile) and 75.60 parts of 1,4-dioxane was added dropwise thereto over 2 hours at 66° C. The resultant mixture was heated at 66° C. for 5 hours. The reaction mixture was cooled down to room temperature and diluted with 92.40 parts of 1,4-dioxane. The resultant mixture was pored into 1092 parts of methanol with stirring to cause precipitation. The precipitate was isolated and washed three times with 546 parts of methanol followed by drying under reduced pressure to obtain 62 parts of a resin having a Mw of 1.53×10⁴, degree of dispersion (Mw/Mn) of 1.47 and Tg of 176° C. The yield thereof was 73%. This resin had the following structural units. This is called as resin A2.

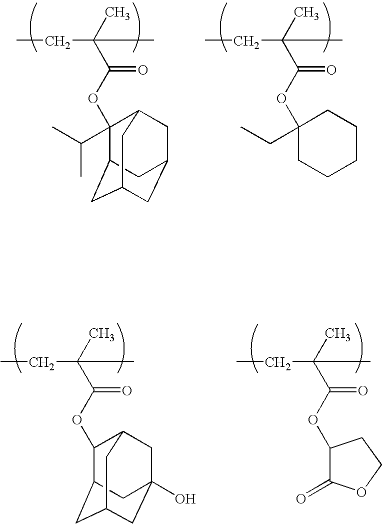

### Salt Synthetic Example 1

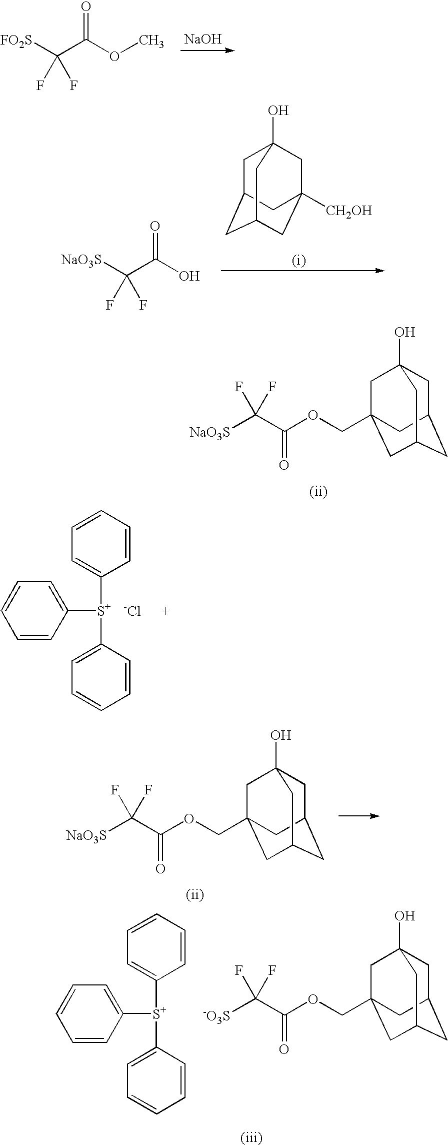 [0226] (1) Into a mixture of 100 parts of methyl difluoro(fluorosulfonyl)acetate and 150 parts of ion-exchanged water, 230 parts of 30% aqueous sodium hydroxide solution was added dropwise in an ice bath. The resultant mixture was heated and refluxed at 100° C. for 3 hours. After cooling down to room temperature, the cooled mixture was neutralized with 88 parts of concentrated hydrochloric acid and the solution obtained was concentrated to obtain 164.4 parts of sodium salt of difluorosulfoacetic acid (containing inorganic salt, purity: 62.7%).
(2) To a mixture of 1.9 parts of sodium salt of difluorosulfoacetic acid (purity: 62.7%) and 9.5 parts of N,N-dimethylformamide, 1.0 part of 1,1′-carbonyldiimidazole was added and the resultant solution was stirred for 2 hours. The solution was added to the solution prepared by mixing 1.1 parts of the compound represented by the above-mentioned formula (1), 5.5 parts of N,N-dimethylformamide and 0.2 part of sodium hydride and stirring for 2 hours. The resultant solution was stirred for 15 hours to obtain the solution containing the salt represented by the above-mentioned formula (Ii).
(3) To the solution containing the salt represented by the above-mentioned formula (ii), 17.2 parts of chloroform and 2.9 parts of 14.8% aqueous triphenylsulfonium chloride solution were added. The resultant mixture was stirred for 15 hours, and then separated to an organic layer and an aqueous layer. The aqueous layer was extracted with 6.5 parts of chloroformto obtain a chloroform layer. The chloroform layer and the organic layer were mixed and washed with ion-exchanged water. The organic layer obtained was concentrated. The residue obtained was mixed with 5.0 parts of tert-butyl methyl ether and the mixture obtained was filtrated to obtain 0.2 part of the salt represented by the above-mentioned formula (iii) in the form of a white solid, which is called as acid generator B1.

### Examples 1 to 2

### Resin

A1: Resin A1
A2: Resin A2
   <Acid generator>
B1: Acid generator B1
   <Cross-linking agent>
C1: “CGPS352” available from Ciba Japan Inc., which is a compound represented by the following formula:

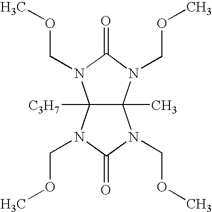

C2: “Powderlink PhenylMethyl” available from Daychem Laboratories, Inc., which is a compound represented by the following formula:

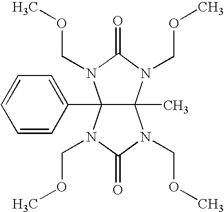

<Basic compound>
Q1: 2,6-diisopropylaniline
Q2: tri(methoxyethoxyethyl)amine

### <Solvent>

| | | |
|---|---|---|
| S1: | propylene glycol monomethyl ether | 290 parts |
| | 2-heptanone | 35 parts |
| | propylene glycol monomethyl ether acetate | 20 parts |
| | γ-butyrolactone | 3 parts |
| S2: | propylene glycol monomethyl ether | 250 parts |
| | 2-heptanone | 35 parts |
| | propylene glycol monomethyl ether acetate | 20 parts |
| | γ-butyrolactone | 3 parts |

The following components were mixed and dissolved, further, filtrated through a fluorine resin filter having pore diameter of 0.2 μm, to prepare photoresist compositions.
Resin (kind and amount are described in Table 2)
Acid generator (kind and amount are described in Table 2)
Cross-linking agent (kind and amount are described in Table 2)
Basic compound (kind and amount are described in Table 2)
Solvent (kind is described in Table 2)

TABLE 2

| | | Acid | Cross- | Basic | |
|---|---|---|---|---|---|
| | Resin | generator | linking | compound | |
| | (kind/ | (kind/ | agent | (kind/ | |
| | amount | amount | (kind/amount | amount | |
| | (part)) | (part)) | (part)) | (part)) | Solvent |
| Composition 1 | A2/10 | B1/0.85 | C1/0.176 | Q2/0.16 | S2 |
| Composition 2 | A2/10 | B1/0.85 | C2/0.193 | Q2/0.16 | S2 |
| Composition 3 | A1/10 | B1/1.5 | — | Q1/0.12 | S1 |

In Example 1, Composition 1 was used as the first photoresist composition, and Composition 3 was used as the second photoresist composition. In Example 2, Composition 2 was used as the first photoresist composition, and Composition 3 was used as the second photoresist composition.

Silicon wafers were each coated with “ARC-29A-8”, which is an organic anti-reflective coating composition available from Brewer Co., and then baked at 205° C. for 60 seconds on a hotplate, to form a 78 nm-thick organic anti-reflective coating. Each of the first photoresist compositions prepared as above was spin-coated over the anti-reflective coating so that the thickness of the resulting film became 95 nm after drying.

Each of the silicon wafers thus coated with the first photoresist composition was prebaked on a hotplate at 120° C. for 60 seconds.

Using an ArF excimer stepper (“FPA-5000AS3” manufactured by CANON INC., NA=0.75, ⅔ Annular), each wafer thus formed with the respective photoresist film was subjected to line and space pattern exposure using a mask having line and space pattern (1:1.5) of which line width was 150 nm with an exposure dose shown in column “Exposure Dose” in Table 3.

After the exposure, each wafer was subjected to a baking on a hotplate at 125° C. for 60 seconds.

After baking, each wafer was subjected to a paddle development for 60 seconds with an aqueous solution of 2.38 wt % tetramethylammonium hydroxide.

After the development, each wafer was baked on a hotplate at the condition shown in column “Condition” in Table 3. The obtained pattern on the organic anti-reflective coating substrate was observed with a scanning electron microscope (“S-4100” manufactured by Hitachi, Ltd.), the space pattern split by the line pattern wherein the line pattern and the space pattern became 1:3 and the line width thereof was 94 nm was formed.

TABLE 3

| | Exposure Dose | |
|---|---|---|
| Example No. | (mJ/cm²) | Condition |
| 1 | 20 | 205° C./25 seconds |
| 2 | 18 | 205° C./25 seconds |

Further, the second photoresist composition prepared as above was spin-coated over the each of wafers on which the first photoresist pattern has been formed so that the thickness of the resulting film became 70 nm after drying.

The silicon wafers thus coated with the second photoresist composition were each prebaked on a hotplate at 85° C. for 60 seconds.

Using an ArF excimer stepper (“FPA-5000AS3” manufactured by CANON INC., NA=0.75, ⅔ Annular), each wafer thus formed with the respective photoresist film was subjected to line and space pattern exposure using a mask having line and space pattern (1:1.5) of which line width was 150 nm with an exposure dose of 38 mJ/cm².

After the exposure, each wafer was subjected to a baking on a hotplate at 85° C. for 60 seconds.

After baking, each wafer was subjected to a paddle development for 60 seconds with an aqueous solution of 2.38 wt % tetramethylammonium hydroxide.

From the observation with a scanning electron microscope (“S-4100” manufactured by Hitachi, Ltd.), the second line pattern was formed between the first line patterns and the pitch thereof became a half of that of the first photoresist pattern.

The shapes of the first and second photoresist patterns were good and the cross sectional shapes of the first and second photoresist patterns were also good, and the good photoresist pattern was obtained.

The leaching properties of the cross-linking agent in the first photoresist compositions were measured as followed;

Silicon wafer was spin-coated with the first photoresist composition so that the thickness of the resulting film became 90 nm after drying. The silicon wafers thus coated with the first photoresist composition were each prebaked on a hotplate at 120° C. for 60 seconds. O-ring which was made by Teflon® and had a diameter of 80 mm was put on the first photoresist film. Onto the photoresist film in the O-ring, 20 mL of pure water was poured. After 10, 30, 60 and 120 seconds, which were referred to as “Contacting Time”, each of the water samples in O-ring was collected using a pipette and analyzed according to the following condition to measure a concentration of the cross-linking agent containing the collected water sample.

### Analytical Condition

Apparatus: Liquid chromatography apparatus (1100 Type) manufactured by AGILENT TECHNOLOGIES LTD., and Mass Spectrometer (LC/MSD TOF Type) manufactured by AGILENT TECHNOLOGIES LTD.
Column: SUMIPAX ODS A-210MS (5 μm×2.0 mm φ×150 mm)

The leaching amounts of the cross-linking agent were plotted in a graph wherein the common logarithm of Contacting Time was X-axis, and the common logarithm of the leaching amount of the cross-linking agent (mol/cm²) was Y-axis. The power approximate equation was obtained based on the graph and then, the leaching amount of the cross-linking agent when Contacting Time is 1 second was calculated from the power approximate equation, which was the leaching amount of the cross-linking agent per unit time. The results are shown in Table 4.

TABLE 4

| Example | Leaching amount |
|---|---|
| No. | (E⁻¹² mol/cm²) |
| Ex. 1 | 0.066 |
| Ex. 2 | 0.099 |

In this art, it is good that the leaching amount of the cross-linking agent per unit time is 1.0×10⁻¹² mol/cm² or less, and therefore, the first photoresist composition used in the present invention has good leaching property.

According to the present invention, the amount of leaching the cross-linking agent into a liquid using in immersion lithography is low and a good photoresist pattern is provided.

What is claimed is:

1. A process for producing a photoresist pattern comprising the following steps (1) to (11):
(1) a step of applying the first photoresist composition comprising:
(a) a resin comprising a structural unit having an acid-labile group in its side chain and being itself insoluble or poorly soluble in an alkali aqueous solution but becoming soluble in an alkali aqueous solution by the action of an acid,
(b) an acid generator, and
(c) a cross-linking agent represented by the formula (X): 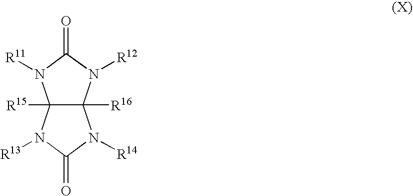
wherein R¹¹, R¹², R¹³ and R¹⁴ each independently represent a C1-C6 alkyl group substituted with a C1-C6 alkoxy group, and R¹⁵ and R¹⁶ each independently represent a C1-C6 alkyl group or a C6-C10 aromatic hydrocarbon group which may have one or more substituents, on a substrate followed by conducting drying, thereby forming the first photoresist film,
(2) a step of prebaking the first photoresist film,
(3) a step of exposing the prebaked first photoresist film to radiation,
(4) a step of baking the exposed first photoresist film,
(5) a step of developing the baked first photoresist film with the first alkaline developer, thereby forming the first photoresist pattern,
(6) a step of making the formed first photoresist pattern inactive to radiation in the following step (9), making the formed first photoresist pattern insoluble in an alkaline developer or making the formed first photoresist pattern insoluble in the second photoresist composition used in the following step (7),
(7) a step of applying the second photoresist composition on the substrate on which the first photoresist pattern has been formed, followed by conducting drying, thereby forming the second photoresist film,
(8) a step of prebaking the second photoresist film,
(9) a step of exposing the prebaked second photoresist film to radiation,
(10) a step of baking the exposed second photoresist film, and
(11) a step of developing the baked second photoresist film with the second alkaline developer, thereby forming the second photoresist pattern.

2. The process according to claim 1, wherein the step (6) is a step of baking the formed first photoresist pattern.

3. The process according to claim 1, wherein R¹¹, R¹², R¹³ and R¹⁴ each independently represent a methoxymethyl group or an isopropoxymethyl group in the formula (X).

4. The process according to claim 1, wherein R¹⁵ and R¹⁶ each independently represent a methyl group, a propyl group or a phenyl group in the formula (X).

5. The process according to claim 1, wherein the amount of the cross-linking agent represented by the formula (X) is 0.5 to 30 parts by weight per 100 parts by weight of the resin in the first photoresist composition.

6. The process according to claim 1, wherein the resin further comprises a structural unit derived from a hydroxyl-containing adamantyl acrylate or a hydroxyl-containing adamantyl methacrylate.

7. The process according to claim 6, wherein the content of the structural unit derived from a hydroxyl-containing adamantyl acrylate or a hydroxyl-containing adamantyl methacrylate is 5 to 50% by mole based on 100% by mole of all of the structural units of the resin.

8. The process according to claim 1, wherein the structural unit having an acid-labile group in its side chain is derived from an acrylic acid ester or a methacrylic acid ester wherein a carbon atom adjacent to the oxygen atom in the ester part is a quaternary carbon atom and the acrylic acid ester and the methacrylic acid ester have 5 to 30 carbon atoms.

9. The process according to claim 1, wherein the content of the resin is 70 to 99.9% by weight based on the amount of solid components in the first photoresist composition.

10. The process according to claim 1, wherein the acid generator is a salt represented by the formula (I): 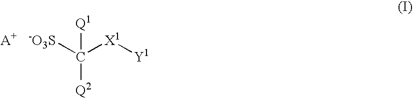
wherein Q1 and Q2 each independently represent a fluorine atom or a C1-C6 perfluoroalkyl group, X¹ represents a single bond or —(CH₂)ₖ—in which one or more methylene groups may be replaced by —O— or —CO—, and one or more hydrogen atoms may be replaced by a linear or branched chain C1-C4 aliphatic hydrocarbon group, and k represents an integer of 1 to 17, Y¹ represents a C3-C36 cyclic hydrocarbon group which may have one or more substituents, and one or more methylene groups in the cyclic hydrocarbon group may be replaced by —O— or —CO—, and A⁺ represents an organic counter ion.

11. The process according to claim 1, wherein the content of the acid generator is 0.1 to 30% by weight based on the amount of solid components in the first photoresist composition.
